(19) United States
(12) Patent Application Publication
(10) Pub. No.: US 2026/0026169 A1
(43) Pub. Date: Jan. 22, 2026

(54) DISPLAY PANEL

(71) Applicant: LG Display Co., Ltd., Seoul (KR)

(72) Inventors: Dan Lyoul MA, Paju-si (KR); Hyoung Sun PARK, Paju-si (KR); Hyun Seok NA, Paju-si (KR)

(73) Assignee: LG Display Co., Ltd., Seoul (KR)

(21) Appl. No.: 19/251,479

(22) Filed: Jun. 26, 2025

(30) Foreign Application Priority Data
Jul. 18, 2024 (KR) 10-2024-0095052

(51) Int. Cl. H10H 29/49; H10H 29/41

(52) U.S. Cl. CPC H10H 29/49; H10H 29/41

(57) ABSTRACT

A display panel according to an embodiment of the present specification can include a substrate having a display area and a non-display area. The display area can include a first-first connection wire, a first-second connection wire arranged on the first-first connection wire, a first-third connection wire arranged on the first-second connection wire, a first-fourth connection wire arranged on the first-third connection wire, and a signal wire arranged on the first-fourth connection wire. At least one protective layer can be arranged on the first-first connection wire or the first-fourth connection wire. Accordingly, corrosion of various wiring in the display device can be prevented and operational reliability can be improved.

### CROSS-REFERENCE TO RELATED APPLICATION

This application claims priority to Korean Patent Application No. 10-2024-0095052, filed in the Republic of Korea on Jul. 18, 2024, the disclosure of which is hereby expressly incorporated by reference in its entirety into the present application.

### BACKGROUND

### Field

The present specification refers to a display panel.

### Discussion of the Related Art

Display devices are employed in various electronic devices such as televisions (TV), mobile phones, laptops, and tablets.

A display device includes an organic light-emitting display (OLED) that emits light by itself and a liquid crystal display (LCD) that requires a separate light source.

Lately, a display device including a light-emitting diode (LED) has attracted attention as a next-generation display device. Since the light-emitting element is made of inorganic materials rather than organic materials, the LED has a faster speed, higher emission efficiency, and higher luminance compared to liquid crystal displays and organic light-emitting displays.

In the manufacturing process of the display device including that of the LED, various wires within the display device can be readily exposed to gases used in the manufacturing process. In addition, these wires can be susceptible to moisture ingress from the outside. If corrosion occurs in the wires due to exposure to gases or moisture ingress, it can lead to technical problems, such as reduced reliability of the display device, requiring possibly expensive and difficult measures to resolve these issues.

### SUMMARY OF THE DISCLOSURE

As described above, external particles such as moisture can penetrate into a display device including an inorganic light-emitting element (e.g., a micro light-emitting diode (a micro LED), reducing the reliability of the display device.

A problem to be solved according to embodiments of the present disclosure is to provide a display panel with improved operation reliability and a display device including the same.

Objectives according to embodiments of the present disclosure are not limited to the above-described objectives, and other objectives that are not described herein will be apparently understood by those skilled in the art from the following description.

A display panel according to an embodiment of the present disclosure can include: a first-first connection wire, a first-second connection wire arranged on the first-first connection wire, a first inorganic layer arranged on the first-first connection wire, a first-third connection wire arranged on the first-second connection wire, a first-fourth connection wire arranged on the first-third connection wire, and a signal wire arranged on the first-fourth connection wire.

A display panel according to an embodiment of the present disclosure can include: a first-first connection wire, a first-second connection wire arranged on the first-first connection wire, a first-third connection wire arranged on the first-second connection wire, a first-fourth connection wire arranged on the first-third connection wire, and a first passivation layer arranged on the first-fourth connection wire.

Specific details according to various examples of the present disclosure other than the means for solving the above-mentioned problems are included in the description and drawings below.

According to the present disclosure, wires that are exposed to gases for a relatively long time during a manufacturing process can be prioritized for protection. Accordingly, the display device according to embodiments can be protected from external moisture ingress, thereby improving operation reliability of the display device.

According to the present disclosure, the display device can achieve reduced manufacturing energy and improve an extended lifespan.

The effects of the present disclosure are not limited to the effects mentioned above, and other effects not mentioned can be clearly understood by those skilled in the art to which the technical idea of the present disclosure pertains from the following description.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, in which:

FIG. 1 is an exploded perspective view of a display device according to an embodiment of the present disclosure.

FIG. 2 is a plan view of the display device according to an embodiment of the present disclosure.

FIG. 3 is a plan view illustrating the display device according to an embodiment of the present disclosure.

FIG. 4 is a plan view of the display device according to an embodiment of the present disclosure.

FIG. 5 is a plan view of the display device according to an embodiment of the present disclosure.

FIG. 6 is a plan view illustrating the display device according to an embodiment of the present disclosure.

FIG. 7 is a plan view illustrating the display device according to an embodiment of the present disclosure.

FIG. 8 is an enlarged view illustrating the display device according to an embodiment of the present disclosure.

FIG. 9 is a diagram illustrating a circuit structure according to an embodiment of the present disclosure.

FIGS. 10 to 23 are cross-sectional views illustrating the display device according to an embodiment of the present disclosure.

FIG. 24 is a diagram illustrating an etching process according to an embodiment of the present disclosure.

FIGS. 25 to 30 are diagrams illustrating the manufacturing process of the display device according to an embodiment of the present disclosure.

FIGS. 31 to 32 are diagrams illustrating the manufacturing process of the display device according to an embodiment of the present disclosure.

FIGS. 33 to 36 are diagrams illustrating an apparatus to which the display device according to embodiments of the present disclosure is applied.

### DETAILED DESCRIPTION OF THE EMBODIMENTS

Advantages and features of the present disclosure and a method of achieving the same should become clear with embodiments described in detail below with reference to the accompanying drawings. However, the present disclosure is not limited to the embodiments described below and can be implemented with a variety of different modifications. The embodiments are merely provided to allow those skilled in the art to completely understand the scope of the present disclosure.

The shapes, dimensions, ratios, angles, numbers, and the like disclosed in the drawings for describing the embodiments of the present disclosure are merely illustrative and are not limited to matters shown in the present disclosure. Like reference numerals refer to like elements throughout the disclosure. Further, in describing the present disclosure, detailed descriptions of well-known technologies will be omitted when it is determined that they can unnecessarily obscure the gist of the present disclosure. Terms such as “including,” “having,” and “composed of” used herein are intended to allow other elements to be added unless the terms are used with the term “only.” Any references to the singular can include the plural unless expressly stated otherwise.

Components are interpreted as including an ordinary error range even if no such margin is explicitly stated.

In the case of a description of a positional relationship, for example, in the case in which a position relationship between two portions is described with the terms “on,” “above,” “under,” “next to,” or the like, one or more portions can be interposed therebetween unless the term, for example, “right”, “directly”, or “near” is used in the expression.

For the description of a temporal relationship, when a temporal relationship is described as “after,” “subsequently to,” “next,” “before,” and the like, a non-consecutive case can be included unless the term “immediately” or “directly” is used in the expression.

Although the terms “first,” “second,” and the like can be used herein to describe various components, the components are not limited by the terms. These terms are used only to distinguish one component from another. Therefore, a first component described below can be a second component within the technological scope of the present disclosure.

Terms such as first, second, A, B, (a), (b), or the like can be used herein when describing components of the present disclosure. Such terms are used only to distinguish a component from another component, but do not limit the nature, sequence, order, number, or the like of components.

It is to be understood that when a component is described as being “connected,” “coupled,” “linked,” or “attached” to another component, the component can be directly connected, coupled, linked, or attached to the other component, but, unless specifically stated otherwise, still another component can be interposed between these two components so that they are indirectly connected, coupled, linked, or attached.

It is also to be understood that when a component or layer is described as being “in contact with” or “overlapping” another component or layer, the component or layer can be in direct contact with or directly overlapping the other component or layer, but, unless specifically stated otherwise, still another component or layer can be interposed between these two components or layers so that they are in indirect contact with or indirectly overlapping each other.

The term “at least one” should be understood as including any and all combinations of one or more of the associated listed components. For example, the meaning of “at least one of a first component, a second component, and a third component” denotes the combination of all components proposed from two or more of the first component, the second component, and the third component as well as the first component, the second component, or the third component.

The terms “first direction,” “second direction,” “third direction,” “X-axis direction,” “Y-axis direction,” and “Z-axis direction” should not be interpreted as referring only to geometrical relationships that are perpendicular to each other, but can indicate a broader range of directions within the functional scope of the configuration described in the present disclosure. The term “can” fully encompasses all the meanings and coverages of the term “may.” The term “made of” for an element can fully encompass the meaning of being completely formed of the element, or simply including the element.

The features of various embodiments of the present disclosure can be partially or entirely combined with each other. The embodiments can be technically linked and operate in various ways and can be carried out independently of or in association with each other.

Hereinafter, various embodiments of the present disclosure will be described in detail with reference to the accompanying drawings.

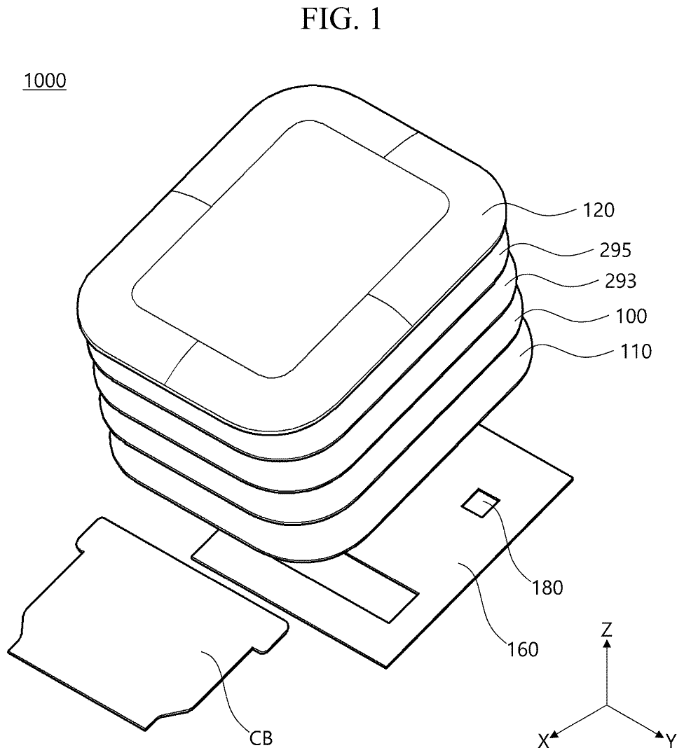

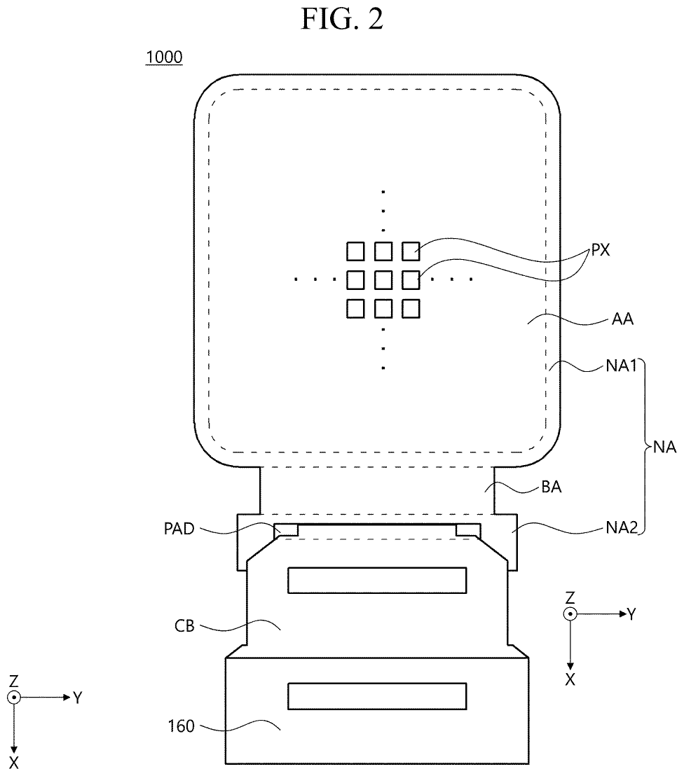

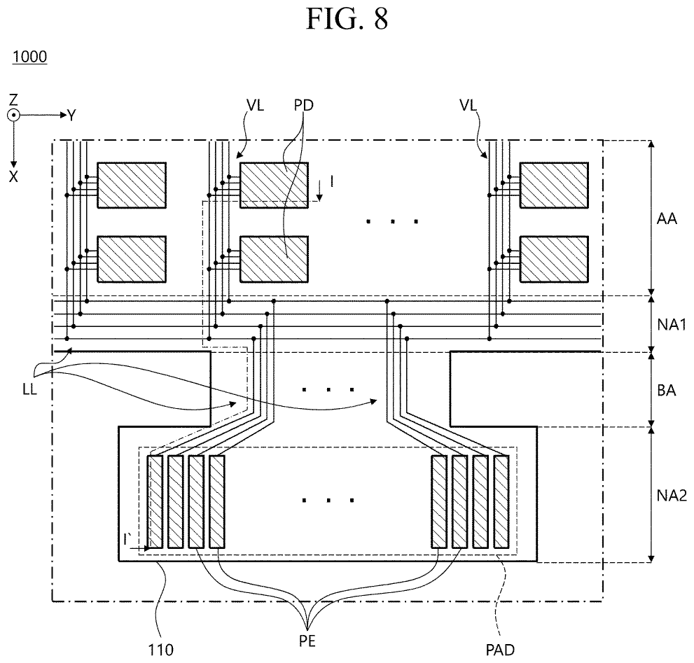

FIG. 1 is an exploded perspective view of a display device according to an embodiment of the present disclosure. FIG. 2 is a plan view of the display device according to an embodiment of the present disclosure. FIG. 8 is an enlarged view illustrating the display device according to an embodiment of the present disclosure. All components of each display device according to all embodiments of the present disclosure are operatively coupled and configured.

Referring to FIGS. 1, 2 and 8, a display device 1000 according to an embodiment of the present disclosure can include a display panel 100, a polarizing layer 293, an adhesive layer 295, a cover member 120, a support substrate 110, a flexible circuit board CB, and a printed circuit board 160.

For example, the display device 1000 can include a substrate 110. The substrate 110 can be a member that supports other components of the display device 1000. The substrate 110 can be made of an insulating material. For example, the substrate 110 can be made of glass or resin. The substrate 110 can also be made of a material having flexibility. For example, the substrate 110 can be made of a plastic material having flexibility, such as polyimide (PI). However, embodiments of the present disclosure are not limited thereto.

The display panel 100 can implement the display of information, video, and/or images intended for the user. For example, the display panel 100 can include a display area AA and a non-display area NA. For example, the substrate 110 can include a display area AA and a non-display area NA. The description of the display area AA and the non-display area NA can be not limited to the substrate 110, but can be applied throughout the display device.

The display area AA can be an area in which images are displayed. The display area AA can include a plurality of pixels PX. Each of a plurality of pixels PX can be composed of a plurality of sub-pixels. Each of the plurality of sub-pixels can have a plurality of light-emitting elements. The plurality of light-emitting elements can be configured differently depending on the type of display device 1000. For example, in the case where the display device 1000 is an inorganic light-emitting display device, the light-emitting elements can be light-emitting diodes (LED), micro light-emitting diodes (micro LED), or mini light-emitting diodes (mini LED), but embodiments of the present disclosure are not limited thereto.

The non-display area NA can be an area in which no image is displayed. Various wires and circuits for driving the plurality of pixels PX in the display area AA can be arranged in the non-display area NA. For example, in the non-display area NA, various wires and driving circuits can be mounted and a pad part PAD can be arranged to which integrated circuits and printed circuits are connected, but embodiments of the present disclosure are not limited thereto.

For example, the driving circuits can be a data driving circuit and/or a gate driving circuit, but embodiments of the present disclosure are not limited thereto. Wires to which control signals for controlling the driving circuits are supplied can be arranged. For example, the control signals can include various timing signals including clock signals, input data enable signals, and synchronization signals, but embodiments of the present disclosure are not limited thereto. The control signals can be received through the pad part PAD. For example, link wires LL for transmitting signals can be arranged in the non-display area NA. For example, driving components such as a flexible circuit board CB and a printed circuit board 160 can be connected to the pad part PAD.

According to the present disclosure, the non-display area NA can include a first non-display area NA1, a bending area BA, and a second non-display area NA2. For example, the first non-display area NA1 can be an area surrounding at least a portion of the display area AA. The bending area BA can be an area extending from at least one of a plurality of sides of the first non-display area NA1, and can be a bendable area. The second non-display area NA2 is an area extending from the bending area BA, in which the pad part PAD can be arranged. For example, the bending area BA can be in a bent state, and the remaining area of the substrate 110 other than the bending area BA can be in a flat state. In this configuration, as the bending area BA is bent, the second non-display area NA2 can be located on the rear surface of the display area AA. However, embodiments of the present disclosure are not limited thereto.

In one embodiment, the display area AA can include an area in which a trench is formed. The area in which the trench is formed can be arranged to enclose a plurality of pixels PX.

The trench can be arranged to enclose a plurality of pixels PX. At least a portion of the trench can be arranged between the plurality of light-emitting elements. The plurality of light-emitting elements can be arranged in the display area AA and/or the first non-display area NA1. The trench can be arranged between the display area AA and the bending area BA. The trench can be arranged between the display panel 100 and the bending area BA. The trench can be arranged between at least a portion of the display panel 100 and the bending area BA.

The display area AA of the substrate 110 or the display device 1000 can be configured in a variety of shapes depending on the design of the display device 1000. For example, the display area AA can be configured as a rectangular shape with four rounded corners, but embodiments of the present disclosure are not limited thereto. For another example, the display area AA can be configured as a rectangular shape with four right-angled corners, a circular shape, or the like, but embodiments of the present disclosure are not limited thereto.

According to the present disclosure, the width of the second non-display area NA2 in which a plurality of pad electrodes PE are arranged can be wider than the width of the bending area BA in which only the plurality of link wires LL are arranged. Furthermore, the width of the display area AA in which the plurality of sub-pixels are arranged can be wider than the width of the bending area BA in which only the plurality of link wires LL is arranged. While the width of the bending area BA is shown to be narrower than the width of other areas of the substrate 110 in this drawing, the shape of the substrate 110 including the bending area BA is an example, and embodiments of the present disclosure are not limited thereto.

Referring to FIG. 8, a plurality of pixel driving circuits PD can be arranged in the display area AA. The plurality of pixel driving circuits PD can be circuits for driving light-emitting elements of a plurality of sub-pixels. Each of the plurality of pixel driving circuits PD includes a plurality of transistors, including a driving transistor, and a storage capacitor or the like, and can supply control signals, power, and driving currents to the light-emitting elements of the plurality of sub-pixels to control the light emission operation of the plurality of light-emitting elements. For example, the pixel driving circuit PD can include power wires and signal wires for controlling the light emission on/off and/or light emission duration of the light-emitting elements. For example, the plurality of pixel driving circuits PD can be drive drivers manufactured on a semiconductor substrate using a metal-oxide-silicon field effect transistor (MOSFET) manufacturing process, but embodiments of the present disclosure are not limited thereto. The drive driver can include the plurality of pixel driving circuits PD and can drive the plurality of sub-pixels.

Referring to FIG. 1 together, the flexible circuit board CB and the printed circuit board 160 can be arranged on a lower portion of the display panel 100. The flexible circuit board CB and the printed circuit board 160 can be arranged on at least one side edge of the display panel 100, but embodiments of the present disclosure are not limited thereto. One side of the flexible circuit board CB can be attached to the display panel 100, and the other side can be attached to the printed circuit board 160, but embodiments of the present disclosure are not limited thereto. The flexible circuit board CB can be a flexible film, but embodiments of the present disclosure are not limited thereto.

The pad part PAD including a plurality of pad electrodes PE can be arranged in the second non-display area NA2. Driving components including one or more flexible circuit boards (or flexible films) CB and the printed circuit board 160 can be attached to or bonded to the pad part PAD. The plurality of pad electrodes PE of the pad part PAD are electrically connected to one or more flexible circuit boards (or flexible film) CB, and various signals (or power) from the printed circuit board 160 and the flexible circuit boards (or flexible films) CB can be transmitted to the plurality of pixel driving circuits PD of the display area AA.

A flexible circuit board (or flexible film) CB can be a film with various components placed on a flexible base film. For example, a drive IC, such as a gate driver IC or a data driver IC, can be arranged on the flexible circuit board (or flexible film) CB, but embodiments of the present disclosure are not limited thereto. The drive IC can be a component that processes data and driving signals for displaying the image. The drive IC can be arranged in a manner such as a chip on glass (COG), a chip on film (COF), or a tape carrier package (TCP), depending on how it is mounted, but embodiments of the present disclosure are not limited thereto. The flexible circuit board (or flexible film) CB can be attached or bonded to the plurality of pad electrodes PE through a conductive adhesive layer, but embodiments of the present disclosure are not limited thereto.

The printed circuit board 160 can be electrically connected to one or more flexible circuit boards (or flexible films) CB and can be a component that supplies signals to the drive IC. The printed circuit board 160 can be arranged on one side of the flexible circuit board (or flexible film) CB and electrically connected to the flexible circuit board (or flexible film) CB. A variety of components for supplying different signals to the drive IC can be arranged on the printed circuit board 160. For example, various components such as a timing controller, a power supply, a memory, or a processor can be arranged on the printed circuit board 160. For example, the printed circuit board 160 can include a power management integrated circuit (PMIC), but embodiments of the present disclosure are not limited thereto.

The printed circuit board 160 can include at least one hole 180, but embodiments of the present disclosure are not limited thereto. An internal component for sensing ambient light or temperature that can be provided to a plurality of sensors can be arranged in an area corresponding to the at least one hole 180. For example, the internal component can include an ambient light sensor (ALS) or a temperature sensor, but embodiments of the present disclosure are not limited thereto. For example, the hole 180 can be a through hole or the like, but embodiments of the present disclosure is not limited thereto.

Referring to FIG. 1, the polarizing layer 293 can be arranged on the display panel 100. The polarizing layer 293 can prevent or reduce light generated from an external light source from entering the interior of the display panel 100 and affecting the light-emitting elements or the like.

The cover member 120 can be arranged on the polarizing layer 293. The cover member 120 can be a member for protecting the display panel 100. The adhesive layer 295 can be arranged between the polarizing layer 293 and the cover member 120. The cover member 120 can be attached to the display panel 100 by the adhesive layer 295. The adhesive layer 295 can include, but is not limited to, an optically clear adhesive (OCA), an optically cleared resin (OCR), or a pressure sensitive adhesive (PSA).

The support substrate 110 can be arranged between the display panel 100 and the printed circuit board 160. The support substrate 110 can reinforce the rigidity of the display panel 100. The support substrate 110 can be a back plate, but embodiments of the present disclosure are not limited thereto.

Referring to FIGS. 1, 2 and 8, a plurality of link wires LL can be arranged in the non-display area NA. The plurality of link wires LL can be wires that carries various signals from one or more flexible circuit boards (or flexible films) CB and the printed circuit board 160 to the display area AA. The plurality of link wires LL can extend from the plurality of pad electrodes PE in the second non-display area NA2 toward the bending area BA and the first non-display area NA1, and can be electrically connected to a plurality of driving wires VL in the display area AA. The plurality of pixel driving circuits PD can be driven by receiving signals from one or more flexible circuit boards (or flexible films) CB and the printed circuit board 160 through the driving wire VL in the display area AA and the link wire LL in the non-display area NA.

For example, a plurality of driving wires VL can be wires for carrying signals output from the flexible circuit board (or flexible film) CB and the printed circuit board 160, along with a plurality of link wires LL, to the plurality of pixel driving circuits PD. The plurality of driving wires VL can be arranged in the display area AA and electrically connected to each of the plurality of pixel driving circuits PD. The plurality of driving wires VL can extend from the display area AA toward the non-display area NA and can be electrically connected to the plurality of link wires LL. Therefore, the signals output from the flexible circuit board (or flexible film) CB and the printed circuit board 160 can be transmitted to each of the plurality of pixel driving circuits PD through the plurality of link wires LL and the plurality of driving wires VL.

As the bending area BA is bent, portions of the plurality of link wires LL can also be bent together. Stress is concentrated in portions of the bent link wires LL, which can cause the link wires LL to crack. Accordingly, the plurality of link wires LL can be formed of a conductive material having excellent ductility to reduce cracking during bending of the bending area BA. For example, the plurality of link wires LL can be formed of a conductive material having excellent ductility such as gold (Au), silver (Ag), and aluminum (Al), but embodiments of the present disclosure are not limited thereto. The plurality of link wires LL can also be formed of one of a variety of conductive materials used in the display area AA. For example, the plurality of link wires LL can be formed of molybdenum (Mo), chromium (Cr), titanium (Ti), nickel (Ni), neodymium (Nd), copper (Cu), and alloys of silver (Ag) and magnesium (Mg), or alloys thereof, but embodiments of the present disclosure are not limited thereto. The plurality of link wires LL can be formed of a multi-layer structure including various conductive materials. For example, the plurality of link wires LL can be formed of a triple-layer structure of titanium (Ti)/aluminum (Al)/titanium (Ti), but embodiments of the present disclosure are not limited thereto.

The plurality of link wires LL can be configured in various shapes to reduce stress. At least a portion of the plurality of link wires LL arranged in the bending area BA can extend in the same direction as the extension of the bending area BA, or can extend in a direction different from the extension of the bending area BA to reduce stress. For example, if the bending area BA extends in one direction from the first non-display area NA1 toward the second non-display area NA2, at least a portion of the link wires LL arranged on the bending area BA can extend in a direction that is inclined relative to the one direction. For another example, at least a portion of the plurality of link wires LL can be configured in a pattern of various shapes. For example, at least a portion of the plurality of link wires LL arranged in the bending area BA can be a shape in which a conductive pattern having at least one of a diamond shape, a rhombus shape, a trapezoidal shape, a triangular wave shape, a sawtooth wave shape, a sinusoidal shape, a circular shape, and an omega shape is repeatedly arranged, but embodiments of the present disclosure are not limited thereto. Therefore, to minimize stresses concentrated in the plurality of link wires LL and resulting cracking, the shape of the plurality of link wires LL can be of various shapes including the shapes described above, but embodiments of the present disclosure are not limited thereto.

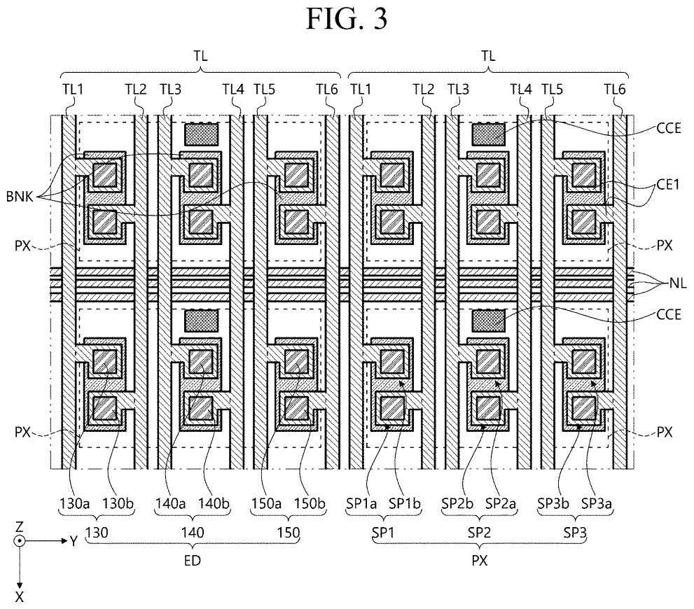

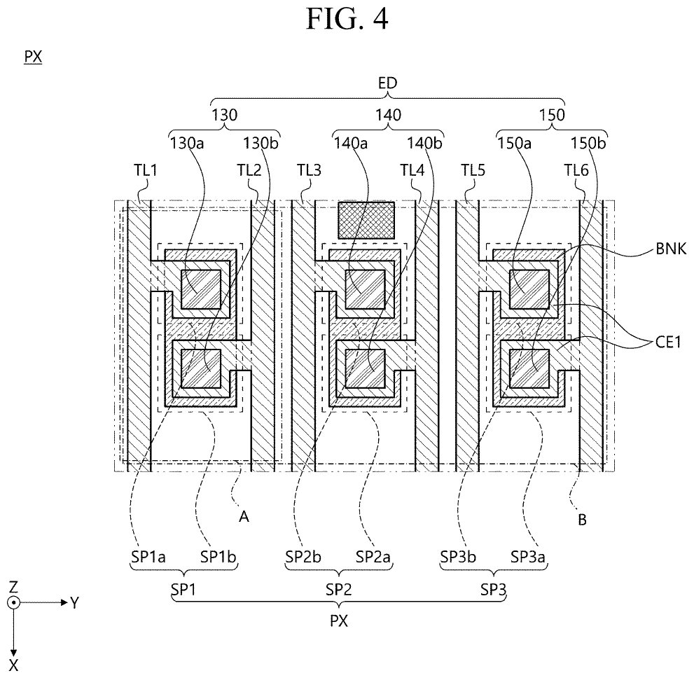

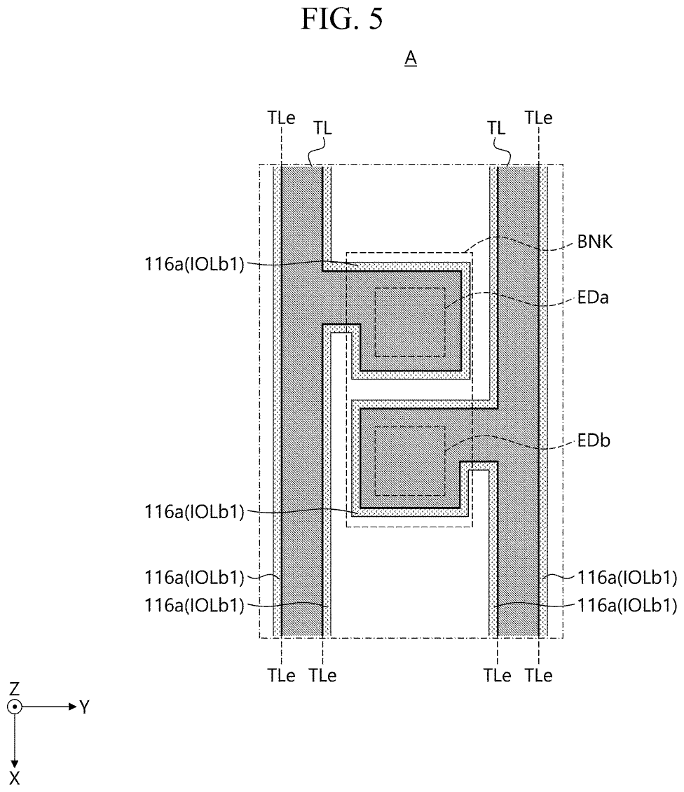

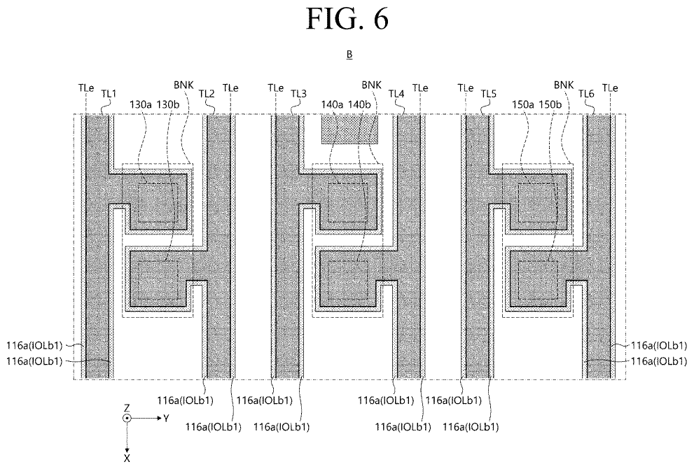

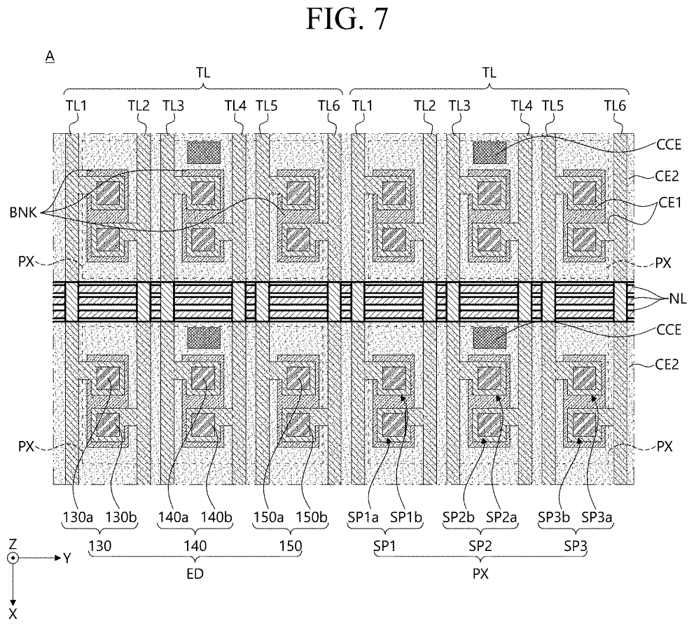

FIG. 3 is a plan view illustrating the display device according to an embodiment of the present disclosure. FIG. 4 is a plan view of the display device according to an embodiment of the present disclosure. FIG. 5 is a plan view of the display device according to an embodiment of the present disclosure. FIG. 6 is a plan view illustrating the display device according to an embodiment of the present disclosure. FIG. 7 is a plan view illustrating the display device according to an embodiment of the present disclosure.

FIG. 5 is a partially enlarged view illustrating an enlargement of portion A of FIG. 4. FIG. 6 is partially enlarged view illustrating an enlargement of portion B of FIG. 4.

While FIGS. 3 and 4 illustrate only a plurality of signal wires TL, a plurality of communication wires NL, a plurality of first electrodes CE1, a plurality of banks BNK, and a plurality of light-emitting elements ED, embodiments of the present disclosure are not limited thereto. FIG. 7 is an enlarged plan view in which a plurality of second electrodes CE2 are additionally arranged in FIG. 3.

Referring to FIGS. 3 to 7, a plurality of pixels PX, each composed of a plurality of sub-pixels, can be arranged in the display area AA. Each of the plurality of sub-pixels can include a light-emitting element ED and can independently emit light. The plurality of sub-pixels can be arranged in a matrix, forming a plurality of rows and a plurality of columns, but embodiments of the present disclosure are not limited thereto.

The plurality of sub-pixels can include a first sub-pixel SP1, a second sub-pixel SP2, and a third sub-pixel SP3. For example, one of the first sub-pixel SP1, the second sub-pixel SP2, and the third sub-pixel SP3 can be a red sub-pixel, another can be a green sub-pixel, and the remaining can be a blue sub-pixel. The types of the plurality of sub-pixels are examples, and embodiments of the present disclosure are not limited thereto.

Each of the plurality of pixels PX can include one or more first sub-pixels SP1, one or more second sub-pixels SP2, and one or more third sub-pixels SP3. For example, one pixel PX can include a pair of first sub-pixels SP1, a pair of second sub-pixels SP2, and a pair of third sub-pixels SP3. A pair of first sub-pixels SP1 can include a first-first sub-pixel SP1a and a first-second sub-pixel SP1b. A pair of second sub-pixels SP2 can include a second-first sub-pixel SP2a and a second-second sub-pixel SP2b. A pair of third sub-pixels SP3 can include a third-first sub-pixel SP3a and a third-second sub-pixel SP3b. For example, one pixel PX can include a first-first sub-pixel SP1a and a first-second sub-pixel SP1b, a second-first sub-pixel SP2a and a second-second sub-pixel SP2b a third-first sub-pixel SP3a and a third-second sub-pixel SP3b, but embodiments of the present disclosure are not limited thereto.

The plurality of sub-pixels that constitute one pixel PX can be arranged in a variety of ways. For example, in one pixel PX, a pair of first sub-pixels SP1 can be arranged in the same column, a pair of second sub-pixels SP2 can be arranged in the same column, and a pair of third sub-pixels SP3 can be arranged in the same column. The first sub-pixel SP1, the second sub-pixel SP2, and the third sub-pixel SP3 can be arranged in the same row. The number and arrangement of the plurality of sub-pixels constituting one pixel PX is an example, and embodiments of the present disclosure are not limited thereto.

A plurality of signal wires TL can be arranged in the area between the plurality of sub-pixels. The plurality of signal wires TL can extend in the column direction between the plurality of sub-pixels. The plurality of signal wires TL can be wires that carry an anode voltage from the pixel driving circuit PD to the plurality of sub-pixels. For example, the plurality of signal wires TL can be electrically connected to the plurality of pixel driving circuits PD and the first electrodes CE1 of the plurality of sub-pixels. The anode voltage output from the pixel driving circuit PD can be transmitted to the first electrodes CE1 of the plurality of sub-pixels through the plurality of signal wires TL. For example, the first electrode CE1 can be an electrode electrically connected to the anode electrode 134 of the light-emitting element ED. Therefore, the anode voltage from the signal wire TL can be transmitted to the anode electrode 134 of the light-emitting element ED through the first electrode CE1.

Consequently, instead of forming a plurality of transistors and storage capacitors for each of a plurality of sub-pixels, the structure of the display device 1000 can be simplified by using a pixel driving circuit PD having a plurality of integrated pixel circuits. Further, by integrating the circuits arranged in each of a plurality of sub-pixels into a single pixel driving circuit PD, high-efficiency, low-power operation can be achieved. The integration of the circuits arranged in each of a plurality of sub-pixels SP into a single pixel driving circuit PD means that a pixel driving circuit PD contains a plurality of pixel circuits that can drive a plurality of light-emitting elements ED. A plurality of light-emitting elements ED can be driven by a single pixel driving circuit PD in which a plurality of pixel circuits are integrated. For example, the first-first light-emitting element 130a, the second-first light-emitting element 140a, and the third-first light-emitting element 150a can be driven by one pixel driving circuit PD in which a plurality of pixel circuits are integrated.

The plurality of signal wires TL can include a first signal wire TL1, a second signal wire TL2, a third signal wire TL3, a fourth signal wire TL4, a fifth signal wire TL5, and a sixth signal wire TL6. Each of the first signal wire TL1 and the second signal wire TL2 can be electrically connected to each of the pair of first sub-pixels SP1. Each of the third signal wire TL3 and the fourth signal wire TL4 can be electrically connected to each of the pair of second sub-pixels SP2. Each of the fifth signal wire TL5 and the sixth signal wire TL6 can be electrically connected to each of the pair of third sub-pixels SP3.

The first signal wire TL1 can be arranged on one side of the pair of first sub-pixels SP1, and the second signal wire TL2 can be arranged on the other side of the pair of first sub-pixels SP1. The first signal wire TL1 can be electrically connected to the first electrode CE1 of one of the pair of first sub-pixels SP1, for example the first-first sub-pixel SP1a. The second signal wire TL2 can be electrically connected to the first electrode CE1 of the remaining of the pair of first sub-pixels SP1, for example, the first-second sub-pixel SP1b.

The third signal wire TL3 can be arranged on one side of the pair of second sub-pixels SP2, and the fourth signal wire TL4 can be arranged on the other side of the pair of second sub-pixels SP2. For example, the third signal wire TL3 can be arranged adjacent to the second signal wire TL2. The third signal wire TL3 can be electrically connected to the first electrode CE1 of one of the pair of second sub-pixels SP2, for example the second-first sub-pixel SP2a. The fourth signal wire TL4 can be electrically connected to the first electrode CE1 of the remaining of the pair of second sub-pixels SP2, for example, the second-second sub-pixel SP2b.

The fifth signal wire TL5 can be arranged on one side of the pair of third sub-pixels SP3, and the sixth signal wire TL6 can be arranged on the other side of the pair of third sub-pixels SP3. For example, the fifth signal wire TL5 can be arranged adjacent to the fourth signal wire TL4. The sixth signal wire TL6 can be arranged adjacent to the first signal wire TL1 connected to its neighboring pixel PX. The fifth signal wire TL5 can be electrically connected to the first electrode CE1 of one of the pair of third sub-pixels SP3, for example the third-first sub-pixel SP3a. The sixth signal wire TL6 can be electrically connected to the first electrode CE1 of the remaining of the pair of third sub-pixels SP3, for example, the third-second sub-pixel SP3b.

The plurality of signal wires TL can be made of a conductive material. For example, the plurality of signal wires TL can be formed of conductive materials such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), and the like, but embodiments of the present disclosure are not limited thereto. For another example, the plurality of signal wires TL can be formed of a multi-layer structure of a conductive material. For example, the plurality of signal wires TL can be formed of a multi-layer structure of Titanium (Ti)/Aluminum (Al)/Titanium (Ti)/Indium Tin Oxide (ITO), but embodiments of the present disclosure are not limited thereto.

The plurality of communication wires NL can be arranged in the area between the plurality of pixels PX. The plurality of communication wires NL can be arranged extending in the row direction in an area between the plurality of pixels PX. The plurality of communication wires NL can be arranged in an area between the plurality of second electrodes CE2, and need not overlap the plurality of second electrodes CE2. For example, the plurality of communication wires NL can be wires used for short-range communication, such as near field communication (NFC). The plurality of communication wires NL can function as antennas. For example, the plurality of communication wires NL can be a plurality of connection wires or the like, but embodiments of the present disclosure are not limited thereto.

According to the present disclosure, a bank BNK can be arranged in each of the plurality of sub-pixels. A plurality of banks BNK can be structures in which a plurality of light-emitting elements ED are seated. The plurality of banks BNK can guide the positioning of the plurality of light-emitting elements ED during a transfer process of transferring a plurality of light-emitting elements ED to the display device 1000. In the process of transferring a plurality of light-emitting elements ED, the plurality of light-emitting elements ED can be transferred onto a plurality of banks BNK. The plurality of banks BNK can be bank patterns or structures, but embodiments of the present disclosure are not limited thereto.

A bank BNK of the first sub-pixel SP1, a bank BNK of the second sub-pixel SP2, and a bank BNK of the third sub-pixel SP3 can be arranged to be spaced apart from each other. The bank BNK of the first sub-pixel SP1, the bank BNK of the second sub-pixel SP2, and the bank BNK of the third sub-pixel SP3 can be configured to be separate. In this way, the banks BNK of the first sub-pixels SP1, the second sub-pixels SP2, and the third sub-pixels SP3, to which different types of light-emitting elements ED are transferred, can be easily identified.

The bank BNK of the first-first sub-pixel SP1a and the bank BNK of the first-second sub-pixel SP1b can be connected to each other, or can be spaced apart from each other or formed separately from each other. For example, the bank BNK of the first-first sub-pixel SP1a and the bank BNK of the first-second sub-pixel SP1b, in which the same type of light-emitting elements ED are arranged, can be connected to each other, spaced apart, or separated from each other in consideration of the design such as the transfer process requirements. The bank BNK of the second-first sub-pixel SP2a and the bank BNK of the second-second sub-pixel SP2b can also be connected to each other, or can also be spaced apart or separated from each other. The bank BNK of the third-first sub-pixel SP3a and the bank BNK of the third-second sub-pixel SP3b can be connected to each other, or can be spaced apart from each other or formed separately from each other. Therefore, the banks BNK of the pair of first sub-pixels SP1, the banks BNK of the pair of second sub-pixels SP2, and the bank BNKs of the pair of third sub-pixels SP3 can be formed in various ways, and embodiments of the present disclosure are not limited thereto.

For example, the plurality of banks BNK can be made of an organic insulating material. The plurality of banks BNK can be formed of a single or multiple layers of an organic insulating material. For example, the plurality of banks BNK can be formed of a photo resist, polyimide (PI), or acryl-based material, but embodiments of the present disclosure are not limited thereto.

The first electrode CE1 can be arranged on each of the plurality of sub-pixels. The first electrode CE1 can be positioned on the bank BNK. The first electrode CE1 can be electrically connected to one of the plurality of signal wires TL. At least a portion of the first electrode CE1 can extend outwardly of the bank BNK and can be electrically connected to the signal wire TL closest to the first electrode CE1. For example, a portion of the first electrode CE1 of the first-first sub-pixel SP1a can extend to one side area of the first-first sub-pixel SP1a and be electrically connected to the first signal wire TL1, and a portion of the first electrode CE1 of the first-second sub-pixel SP1b can extend to the other side area of the first-second sub-pixel SP1b and be electrically connected to the second signal wire TL2. A portion of the first electrode CE1 of the second-first sub-pixel SP2a can extend to one side area of the second-first sub-pixel SP2a and be electrically connected to the third signal wire TL3, and a portion of the first electrode CE1 of the second-second sub-pixel SP2b can extend to the other side of the second-second sub-pixel SP2b and be electrically connected to the fourth signal wire TL4. A portion of the first electrode CE1 of the third-first sub-pixel SP3a can extend into one side area of the third-first sub-pixel SP3a and be electrically connected to the fifth signal wire TL5, and a portion of the first electrode CE1 of the third-second sub-pixel SP3b can extend into the other side area of the third-second sub-pixel SP3b and be electrically connected to the sixth signal wire TL6.

The first electrode CE1 is electrically connected to an anode electrode 134 of the light-emitting element ED, and can transmit the anode voltage from the pixel driving circuit PD to the light-emitting element ED via the signal wire TL. Different voltages can be applied to the first electrode CE1 of each of the plurality of sub-pixels depending on the image being displayed. For example, different voltages can be applied to the first electrode CE1 of each of the plurality of sub-pixels. The first electrode CE1 can be a pixel electrode, and embodiments of the present disclosure are not limited thereto.

The first electrode CE1 can be formed of a conductive material. For example, the first electrode CE1 can be integrally formed with the plurality of signal wires TL. For example, the first electrode CE1 can be formed of the same conductive material as the plurality of signal wires TL, but embodiments of the present disclosure are not limited thereto. For example, the first electrode CE1 can be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), and the like, but embodiments of the present disclosure are not limited thereto. For another example, the first electrode CE1 can be formed of a multi-layer structure of a conductive material. For example, the plurality of first electrodes CE1 can be made of a multi-layer structure of Titanium (Ti)/Aluminum (Al)/Titanium (Ti)/Indium Tin Oxide (ITO), but embodiments of the present disclosure are not limited thereto.

A light-emitting element ED can be arranged in each of the plurality of sub-pixels. A plurality of light-emitting elements ED can be either light-emitting diodes (LED) or micro light-emitting diodes (micro LED), but embodiments of the present disclosure are not limited thereto. The plurality of light-emitting elements ED can be arranged on the bank BNK and the first electrode CE1. The plurality of light-emitting elements ED are arranged on the first electrode CE1 and can be electrically connected to the first electrode CE1. Therefore, the light-emitting element ED can emit light by receiving an anode voltage from the pixel driving circuit PD via the signal wire TL and the first electrode CE1.

The plurality of light-emitting elements ED can include a first light-emitting element 130, a second light-emitting element 140, and a third light-emitting element 150. The first light-emitting element 130 can be arranged in the first sub-pixel SP1. The second light-emitting element 140 can be arranged in the second sub-pixel SP2. The third light-emitting element 150 can be arranged in the third sub-pixel SP3. For example, one of the first light-emitting element 130, the second light-emitting element 140, and the third light-emitting element 150 can be a red light-emitting element, another can be a green light-emitting element, and the remaining can be a blue light-emitting element, but embodiments of the present disclosure are not limited thereto. Accordingly, various colors of light, including white, can be implemented by combining red light, green light, and blue light emitted by the plurality of light emitting elements ED. The types of the plurality of light-emitting elements ED are examples, and embodiments of the present disclosure are not limited thereto.

The size of each light-emitting element ED can vary from color to color. For example, the size of the first light-emitting element 130 can be different from the size of the second light-emitting element 140 and the third light-emitting element 150.

The first light-emitting element 130 can include the first-first light-emitting element 130a arranged in the first-first sub-pixel SP1a and the first-second light-emitting element 130b arranged in the first-second sub-pixel SP1b. The second light-emitting element 140 can include the second-first light-emitting element 140a arranged in the second-first sub-pixel SP2a and the second-second light-emitting element 140b arranged in the second-second sub-pixel SP2b. The third light-emitting element 150 can include a third-first light-emitting element 150a arranged in the third-first sub-pixel SP3a and the third-second light-emitting element 150b arranged in the third-second sub-pixel SP3b.

The second electrode CE2 can be arranged on each of the plurality of sub-pixels. The second electrode CE2 can be arranged on the light-emitting element ED. The second electrode CE2 can be electrically connected to the pixel driving circuit PD via a plurality of contact electrodes CCE.

For example, the second electrode CE2 can be electrically connected to a cathode electrode 135 of the light-emitting element ED to transmit the cathode voltage from the pixel driving circuit PD to the light-emitting element ED. The same cathode voltage can be applied to the second electrode CE2 of each of the plurality of sub-pixels. For example, the same voltage can be applied to the second electrode CE2 of each of the plurality of sub-pixels and the cathode electrode 135 of the light-emitting element ED. Thus, the second electrode CE2 can be a common electrode, but embodiments of the present disclosure are not limited thereto.

At least some of the plurality of sub-pixels can share the second electrode CE2. At least some of the second electrodes CE2 of the plurality of sub-pixels can be electrically connected to each other. Since the same voltage is applied to the second electrodes CE2, at least some of the second electrodes CE2 of the sub-pixels can be shared and used. For example, the second electrodes CE2 of at least some of the plurality of pixels PX arranged in the same row can be connected to each other. For example, one second electrode CE2 can be arranged on a plurality of pixels PX. One second electrode CE2 can be arranged for every n sub-pixels.

For example, some of the second electrodes CE2 of the plurality of sub-pixels can be spaced apart or separated from each other. For example, a second electrode CE2 connected to the pixels PX in an (n)th row and a second electrode CE2 connected to the pixels PX in an (n+1)th row can be spaced apart or separated from each other. For example, a plurality of second electrodes CE2 can be spaced apart from each other with a plurality of communication wires NL extending in the row direction interposed therebetween. Thus, the number of a plurality of sub-pixels can be greater than the number of a plurality of second electrodes CE2. For another example, the second electrodes CE2 of the plurality of sub-pixels can all be connected to each other so that only one second electrode CE2 is arranged on the substrate 110, and embodiments of the present disclosure are not limited thereto.

The plurality of second electrodes CE2 can be formed of a transparent conductive material, but embodiments of the present disclosure are not limited thereto. The plurality of second electrodes CE2 can be made of a transparent conductive material, such that light emitted from the light-emitting element ED is directed toward the top of the second electrode CE2. For example, the second electrode CE2 can made of a transparent conductive material such as Indium Tin Oxide (ITO), Indium Zinc Oxide (IZO), Indium Gallium Zinc Oxide (IGZO), or the like, but embodiments of the present disclosure are not limited thereto.

A plurality of contact electrodes CCE can be positioned on the substrate 110. For example, a plurality of contact electrodes CCE can be positioned to be spaced apart from the plurality of banks BNK and the plurality of signal wire TL. Each of the plurality of second electrodes CE2 can overlap at least one contact electrode CCE. For example, one second electrode CE2 can overlap a plurality of contact electrodes CCE.

For example, a plurality of contact electrodes CCE can be electrically connected to a plurality of second electrodes CE2. The plurality of contact electrodes CCE are arranged between the substrate 110 and the plurality of second electrodes CE2 to supply the cathode voltage from the pixel driving circuit PD to the second electrodes CE2.

For example, if micro-LEDs are used as the light-emitting elements ED, the display device 1000 can be manufactured by forming a plurality of micro-LEDs on a wafer and transferring the micro-LEDs to the substrate 110 of the display device 1000. Various defects can occur in the process of transferring a plurality of light-emitting elements ED having a fine size from a wafer to the substrate 110. For example, some sub-pixels can exhibit non-transferred defects in which the light-emitting element ED is not transferred, while other sub-pixels can exhibit misalignment defects in which the light-emitting element ED is transferred out of position due to misalignment. In addition, even if the transfer process has been completed normally, the transferred light-emitting element ED itself can be defective. Accordingly, considering potential defects during the transfer process of multiple light-emitting elements ED, a plurality of identical light-emitting elements ED can be transferred to a single sub-pixel. A test for lighting a plurality of light-emitting elements ED is conducted, and only one light-emitting element ED that is finally judged to be normal can be used.

For example, the first-first light-emitting element 130a and the first-second light-emitting element 130b can be transferred together to one pixel PX and inspected for defects. If both the first-first light-emitting element 130a and the first-second light-emitting element 130b are determined to be normal, only the first-first light-emitting element 130a can be used and the first-second light-emitting element 130b need not be used. For another example, if only the first-second light-emitting element 130b among the first-first light-emitting element 130a and the first-second light-emitting element 130b is determined to be normal, the first-first light-emitting element 130a need not be used and only the first-second light-emitting element 130b can be used. Therefore, even if a plurality of light-emitting elements ED of the same type are transferred to one pixel PX, only one light-emitting element ED can be used at the end.

Thus, one of the pair of light-emitting elements ED can be the main or primary ED and the other can be a redundancy ED. A redundancy light-emitting element ED can be a spare light-emitting element ED in preparation for a defect in the main light-emitting element ED. The redundancy light-emitting element ED can be used as a replacement in case the main light-emitting element ED is defective. Accordingly, the main and redundancy light-emitting elements ED can be transferred together on one pixel PX to minimize the deterioration of the display quality due to the defects of the main and redundancy light-emitting elements ED.

For example, the first-first light-emitting element 130a, second-first light-emitting element 140a, and third-first light-emitting element 150a transferred to one pixel PX can be used as the main light-emitting elements ED, and the first-second light-emitting element 130b, second-second light-emitting element 140b, and third-second light-emitting element 150b can be used as the redundancy light-emitting elements ED.

Referring to FIGS. 5 and 6, on a plane, a first passivation layer 116a can be formed to surround a border of the signal wire TL. As will be described later, the signal wire TL is a structure with a plurality of metal layers stacked, and the first passivation layer 116a can include an inorganic layer IOLb1 surrounding a border or end of the plurality of metal layers and an inorganic layer arranged on the top of the plurality of metal layers. The first passivation layer 116a can be formed to correspond to the shape of the signal wire TL to protect the signal wire TL.

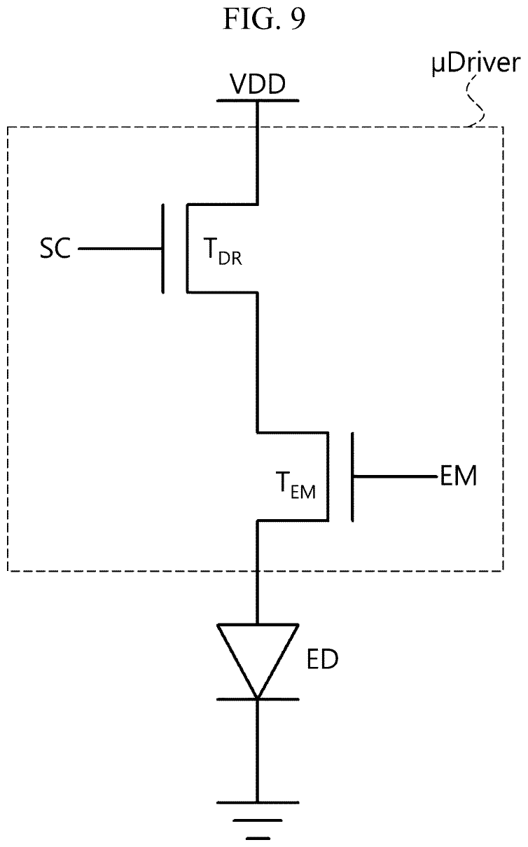

FIG. 9 is a diagram illustrating a circuit structure according to an embodiment of the present disclosure.

Although FIG. 9 illustrates that one light-emitting element ED is connected to a micro driver μDriver, it is not limited thereto. For example, eight light-emitting elements ED can be connected to one micro-driver μDriver. For another example, 16 light-emitting elements ED can be connected to one micro-driver, or 32 light-emitting elements ED or 64 light-emitting element ED can be connected to one micro-driver simultaneously. The light-emitting element ED can be a micro light-emitting element μLED.

One micro-driver μDriver can include a driving transistor TDR and a light-emitting transistor TEM, but embodiments of the present disclosure are not limited thereto.

For example, the driving transistor TDR can have a first electrode to which a high potential power voltage VDD is applied, a second electrode connected to a first electrode of the light-emitting transistor TEM, and a gate electrode to which a scan signal SC is applied. The scan signal SC applied to the gate electrode of the driving transistor TDR can be a direct current voltage, and a fixed reference voltage (Vref) is applied for each frame, but embodiments of the present disclosure are not limited thereto.

The light-emitting transistor TEM can have a first electrode connected to the second electrode of the driving transistor TDR, a second electrode connected to the light-emitting element ED, and a gate electrode to which an emission signal EM is applied. The emission signal EM applied to the gate electrode of the light-emitting transistor TEM can be a pulse width modulation signal that varies every frame, but embodiments of the present disclosure are not limited thereto.

The light-emitting element ED can have a first electrode connected to a second electrode of the light-emitting transistor TEM and a second electrode to ground. For example, the first electrode can be an anode electrode and the second electrode can be a cathode electrode, but embodiments of the present disclosure are not limited thereto.

Each of the driving transistor TDR and the light-emitting transistor TEM can be n-type transistors or p-type transistors.

In the micro-driver Driver, the driving transistor TDR can be turned on by the scan signal SC applied from the timing controller T-CON, and the light-emitting transistor TEM can be turned on by the light-emitting signal EM. Accordingly, a driving current is applied to the light-emitting element ED through the driving transistor TDR and the light-emitting transistor TEM by the high-potential power voltage VDD applied to the first electrode of the driving transistor TDR, thereby causing the light-emitting element ED to emit light.

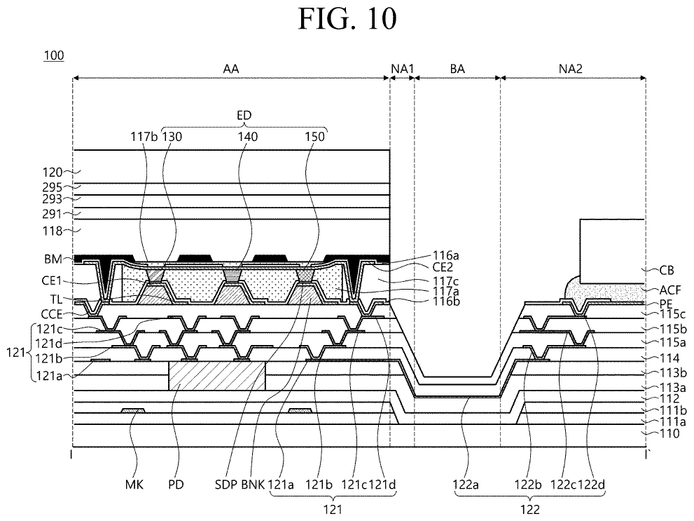

FIG. 10 is a cross-sectional view illustrating the display device according to an embodiment of the present disclosure.

FIG. 10 is cross-sectional view of the display area AA, the first non-display area NA1, the bending area BA, and the second non-display area NA2. FIG. 10 is a cross-sectional view taken along line I-I′ FIG. 8.

Referring to FIG. 10, a first buffer layer 111a and a second buffer layer 111b can be arranged on the remaining areas of the substrate 110 except for the bending area BA.

The first buffer layer 111a and the second buffer layer 111b can be arranged in the display area AA, the first non-display area NA1, and the second non-display area NA2. The first buffer layer 111a and the second buffer layer 111b can reduce the ingress of moisture or impurities through the substrate 110. The first buffer layer 111a and the second buffer layer 111b can be made of an inorganic insulating material. For example, the first buffer layer 111a and the second buffer layer 111b can be formed of a single layer or a multi-layer of silicon oxide (SiOx) or silicon nitride (SiNx), but embodiments of the present disclosure are not limited thereto.

For example, portions of the first buffer layer 111a and the second buffer layer 111b on the bending area BA can be removed. The top surface of the substrate 110 positioned in the bending area BA can be exposed from the first buffer layer 111a and the second buffer layer 111b. By removing the first buffer layer 111a and the second buffer layer 111b, which are made of an inorganic insulating material, from the bending area BA, cracking of the first buffer layer 111a and the second buffer layer 111b that can occur during bending can be minimized.

A plurality of alignment keys MK can be positioned between the first buffer layer 111a and the second buffer layer 111b. The plurality of alignment keys MK can be configured to identify position of the pixel driving circuit PD during the manufacturing process of the display device 1000. For example, the plurality of alignment keys MK can be configured to align the position of the pixel driving circuit PD that is transferred onto the adhesive layer 112. In another example, the plurality of alignment keys MK can be omitted.

An adhesive layer 112 can be arranged on the second buffer layer 111b. The adhesive layer 112 can be arranged in the display area AA and the first non-display area NA1, and the bending area BA and the second non-display area NA2. For another example, at least a portion of the adhesive layer 112 can be removed from the non-display area NA that includes the bending area BA. For example, the adhesive layer 112 can be made of any of a polymer, epoxy resin, UV curable resin, polyimide-based, acrylate-based, urethane-based, and polydimethylsiloxane (PDMS), but embodiments of the present disclosure are not limited thereto.

In the display area AA, the pixel driving circuit PD can be arranged on the adhesive layer 112. If the pixel driving circuit PD is implemented as a drive driver, the drive driver can be mounted on the adhesive layer 112 by a transfer process, but embodiments of the present disclosure are not limited thereto.

A first protective layer 113a and a second protective layer 113b can be arranged on the adhesive layer 112 and the pixel driving circuit PD. The first protective layer 113a and the second protective layer 113b can be arranged to surround the side surfaces of the pixel driving circuit PD, but embodiments of the present disclosure are not limited thereto. For example, the second protective layer 113b can be arranged to cover at least a portion of the top surface of the pixel driving circuit PD. For example, at least one of the first protective layer 113a and the second protective layer 113b arranged on the bending area BA can be omitted. For example, the first protective layer 113a can be arranged entirely in the display area AA and the non-display area NA, and the second protective layer 113b can be arranged partially in the display area AA, the first non-display area NA1, and the second non-display area NA2. For example, a portion of the second protective layer 113b in the bending area BA can be removed. However, embodiments of the present disclosure are not limited thereto.

The first protective layer 113a and the second protective layer 113b can be formed of an organic insulating material, but embodiments of the present disclosure are not limited thereto. For example, the first protective layer 113a and the second protective layer 113b can be formed of a photo resist, polyimide (PI), or photo acryl-based material, but embodiments of the present disclosure are not limited thereto. For example, the first protective layer 113a and the second protective layer 113b can be an overcoating layer or an insulating layer, but embodiments of this disclosure are not limited thereto.

According to the present disclosure, a plurality of first connection wires 121 can be arranged on the second protective layer 113b in the display area AA. The plurality of first connection wires 121 can be wires for electrically connecting the pixel driving circuit PD to other components. For example, the pixel driving circuit PD can be electrically connected through a plurality of first connection wires 121 to a plurality of signal wires TL and a plurality of contact electrodes CCE. For example, a plurality of first connection wires 121 can include a first-first connection wire 121a, a first-second connection wire 121b, a first-third connection wire 121c, and a first-fourth connection wire 121d, but embodiments of the present disclosure are not limited thereto.

For example, a plurality of first-first connection wire 121a can be arranged on the second protective layer 113b. The plurality of first-first connection wires 121a can be electrically connected to the pixel driving circuit PD. The plurality of first-first connection wires 121a can transmit the voltage output from the pixel driving circuit PD to the first electrode CE1 or the second electrode CE2.

For example, a third protective layer 114 can be arranged on the second protective layer 113b. The third protective layer 114 can be entirely arranged in the display area AA and the non-display area NA. In the bending area BA, the third protective layer 114 can cover the side surface of the second protective layer 113b and the top surface of the first protective layer 113a. The third protective layer 114 can be formed of an organic insulating material. For example, the third protective layer 114 can be formed of a photo resist, polyimide (PI), or photo acryl-based material, but embodiments of the present disclosure are not limited thereto. For example, the first protective layer 113a, the second protective layer 113b, and the third protective layer 114 can be formed of the same material, but embodiments of the present disclosure are not limited thereto.

The plurality of first-second connection wires 121b can be arranged on the third protective layer 114. The plurality of first-second connection wires 121b can be connected to or directly connected to the pixel driving circuit PD. For example, some of the first-second connection wires 121b can be directly connected to the pixel driving circuit PD through contact holes in the third protective layer 114. The other of the first-second connection wires 121b can be electrically connected to the first-first connection wire 121a through the contact holes in the third protective layer 114. However, embodiments of the present disclosure are not limited thereto. The voltage output from the pixel driving circuit PD can be transmitted to the first electrode CE1 or the second electrode CE2 through connection wires other than the plurality of first-second connection wires 121b.

A first insulating layer 115a can be formed on the plurality of first-second connection wires 121b. The first insulating layer 115a can be entirely arranged in the display area AA and the non-display area NA, but embodiments of the present disclosure are not limited thereto. The first insulating layer 115a can be formed of an organic insulating material, but embodiments of the present disclosure are not limited thereto. For example, the first insulating layer 115a can be formed of a photo resist, polyimide (PI), or photo acryl-based material, but embodiments of the present disclosure are not limited thereto.

A plurality of first-third connection wires 121c can be arranged on the first insulating layer 115a. The first-third connection wires 121c can be electrically connected to the plurality of first-second connection wire 121b. For example, the first-third connection wires 121c can be electrically connected to the first-second connection wires 121b through contact holes of the first insulating layer 115a.

A second insulating layer 115b can be arranged on the plurality of first-third connection wires 121c. The second insulating layer 115b can be arranged in the remaining area except for the bending area BA, but embodiments of the present disclosure are not limited thereto. The second insulating layer 115b can be arranged in the display area AA, the first non-display area NA1, and the second non-display area NA2, but embodiments of the present disclosure are not limited thereto. For example, a portion of the second insulating layer 115b arranged in the bending area BA can be removed. The second insulating layer 115b can be formed of an organic insulating material, but embodiments of the present disclosure are not limited thereto. For example, the second insulating layer 115b can be formed of a photo resist, polyimide (PI), or photo acryl-based material, but embodiments of the present disclosure are not limited thereto.

A plurality of first-fourth connection wires 121d can be arranged on the second insulating layer 115b. The plurality of first-fourth connection wires 121d can be electrically connected to the plurality of first-third connection wires 121c. For example, the first-fourth connection wires 121d can be electrically connected to the first-third connection wires 121c through contact holes of the second insulating layer 115b.

According to the present disclosure, the plurality of second connection wires 122 can be arranged on the second protective layer 113b in the non-display area NA. The plurality of second connection wires 122 can be wires for transmitting signals, which have been transmitted to the pad part PAD from the flexible circuit board (or flexible film) CB and the printed circuit board 160 (see FIG. 1), to the pixel driving circuit PD of the display area AA. For example, the plurality of second connection wires 122 can be electrically connected to the plurality of pad electrodes PE to receive signals from the flexible circuit board (or flexible film) CB and the printed circuit board.

For example, the plurality of second connection wires 122 can extend from the pad part PAD toward the display area AA to transmit signals to the wires in the display area AA. In this case, the plurality of second connection wires 122 can function as the link wires LL. The plurality of second connection wires 122 can include a second-first connection wire 122a, a second-second connection wire 122b, a second-third connection wire 122c, and a second-fourth connection wire 122d.

A plurality of second-first connection wires 122a can be arranged on the second protective layer 113b. The plurality of second-first connection wires 122a can extend from the second non-display area NA2 to the bending area BA and the first non-display area NA1. The plurality of second-first connection wire 122a can transmit signals, which have been transmitted to the pad part PAD from the flexible circuit board (or flexible film) CB and the printed circuit board, to the pixel driving circuit PD of the display area AA.

A plurality of second-second connection wires 122b can be arranged on the third protective layer 114. The plurality of second-second connection wires 122b can be arranged on the second non-display area NA2. The second-second connection wires 122b can be electrically connected to the second-first connection wires 122a through contact holes in the third protective layer 114. Thus, the signals from the flexible circuit board (or flexible film) (CB) and the printed circuit board can be transmitted to the second-first connection wires 122a through the second-second connection wires 122b.

A plurality of second-third connection wires 122c can be arranged on the first insulating layer 115a. The second-third connection wires 122c can be arranged on the second non-display area NA2. The second-third connection wires 122c can be electrically connected to the second-second connection wires 122b through contact holes in the first insulating layer 115a. Thus, signals from the flexible circuit board (or flexible film) (CB) and the printed circuit board can be transmitted to the second-first connection wires 122a through the second-third connection wires 122c and the second-second connection wires 122b.

A plurality of second-fourth connection wires 122d can be arranged on the second insulating layer 115b. The second-fourth connection wires 122d can be arranged on the second non-display area NA2. The second-fourth connection wires 122d can be electrically connected to the second-third connection wires 122c through contact holes in the second organic insulating layer 115b. Thus, the signals from the flexible film (FF) and the printed circuit board can be transmitted to the second-first connection wires 122a through the second-fourth connection wires 122d, the second-third connection wires 122c, and the second-second connection wire 122b.

The plurality of first connection wires 121 and the plurality of second connection wires 122 can be formed of any one of a conductive material having excellent ductility or various conductive materials used in the display area AA. For example, the second connection wire 122, a portion of which is arranged in the bending area BA, can be made of a conductive material having excellent ductility, such as gold (Au), silver (Ag), or aluminum (Al), but embodiments of the present disclosure are not limited thereto. For example, the plurality of first connection wires 121 and the plurality of second connection wires 122 can be formed of molybdenum (Mo), chromium (Cr), titanium (Ti), nickel (Ni), neodymium (Nd), copper (Cu), aluminum (Al), and alloys of silver (Ag) and magnesium (Mg), a multi-layer stack-up of these materials, or alloys thereof, but embodiments of the present disclosure are not limited thereto.

A third insulating layer 115c can be arranged on the plurality of first connection wires 121 and the plurality of second connection wires 122. The third insulating layer 115c can be arranged in the remaining area except for the bending area BA, but embodiments of the present disclosure are not limited thereto. The third insulating layer 115c can be arranged in the display area AA, the first non-display area NA1, and the second non-display area NA2. A portion of the third insulating layer 115c in the bending area BA can be removed. The third insulating layer 115c can be formed of an organic insulating material, but embodiments of the present disclosure are not limited thereto. For example, the third insulating layer 115c can be formed of a photo resist, polyimide (PI), or photo acryl-based material, but embodiments of the present disclosure are not limited thereto.

In the display area AA, a plurality of banks BNK can be arranged on the third insulating layer 115c. The plurality of banks BNK can be arranged to overlap each of the plurality of sub-pixels. One or more light-emitting elements ED of the same type can be arranged over each of the plurality of banks BNK.

In the display area AA, the plurality of signal wires TL can be arranged on the third insulating layer 115c. The plurality of signal wires TL can be arranged in an area between the plurality of banks BNK. For example, the plurality of signal wires TL can be arranged adjacent to any one of the plurality of banks BNK.

A plurality of contact electrodes CCE can be arranged on the third insulating layer 115c in the display area AA. The plurality of contact electrodes CCE can supply the cathode voltage from the pixel driving circuit PD to the second electrode CE2.

The first electrode CE1 can be arranged on the bank BNK. For example, the first electrode CE1 can be arranged extending from the adjacent signal wire TL toward the upper portion of the bank BNK. The first electrode CE1 can be arranged on the top surface of the bank BNK and the side surface of the bank BNK. For example, the first electrode CE1 can be arranged extending from the signal wire TL on the top surface of the third insulating layer 115c to the side surface of the bank BNK and to the top surface of the bank BNK.

The signal wire TL can be formed of substantially the same thickness as the first-third connection wire 121c. The first-first connection wire 121a, the first-second connection wire 121b, and the first-fourth connection wire 121d can be formed of substantially the same thickness as each other. The first-first connection wire 121a can be formed to have a relatively greater thickness than the signal line TL. The thickness of the first-first connection wire 121a can be 140% to 210% of the thickness of the signal wire TL. Alternatively, it can be 160% to 190%.

In the display area AA, a first optical layer 117a can be arranged to surround the plurality of light-emitting elements ED. For example, the first optical layer 117a can be arranged to cover the plurality of light-emitting elements ED and banks BNK in a plurality of sub-pixel regions. For example, the first optical layer 117a can cover between the bank BNK, a portion of the first passivation layer 116a, and the plurality of light-emitting elements ED. The first optical layer 117a can be arranged between or covering the plurality of light-emitting elements ED included in one pixel PX and between or covering the plurality of banks BNK. For example, the first optical layer 117a can extend in the first direction (X-axis direction), and can be spaced apart from the second direction (Y-axis direction). For example, the first optical layer 117a can be arranged to surround the side portions of the light-emitting element ED and the bank BNK between the first passivation layer 116a and the second electrode CE2, but embodiments of the present disclosure are not limited thereto. For example, the first optical layer 117a can be a diffusion layer, a sidewall diffusion layer, or the like, but embodiments of the present disclosure are not limited thereto.

The first optical layer 117a can include an organic insulating material in which fine particles are dispersed, but embodiments of the present disclosure are not limited thereto. For example, the first optical layer 117a can be formed of siloxane in which fine metal particles such as titanium dioxide (TiO₂) particles are dispersed, but embodiments of the present disclosure are not limited thereto. Light from the plurality of light-emitting elements ED can be scattered by the fine particles dispersed in the first optical layer 117a and emitted to the outside of the display device 1000. This can ensure that the first optical layer 117a improves the extraction efficiency of light emitted from the plurality of light-emitting elements ED.

For example, the first optical layer 117a can be arranged in each of the plurality of pixels PX, or can be arranged together in some of the pixels PX arranged in the same row, but embodiments of the present disclosure are not limited thereto. For example, the first optical layer 117a can be arranged in each of the plurality of pixels PX, or one first optical layer 117a can be shared by the plurality of pixels PX. For another example, each of the plurality of sub-pixels can separately include the first optical layer 117a, but embodiments of the present disclosure are not limited thereto.

According to the disclosure, the third optical layer 117c can be arranged on the first passivation layer 116a in the display area AA. For example, the third optical layer 117c can be arranged to surround the first optical layer 117a. For example, the third optical layer 117c can abut the side surface of the first optical layer 117a. For example, the third optical layer 117c can be arranged in an area between the plurality of pixels PX. However, embodiments of the present disclosure are not limited thereto. For example, the third optical layer 117c can be a diffusion layer, a diffusion layer window, or a window diffusion layer, but embodiments of the present disclosure are not limited thereto.

The third optical layer 117c can be formed of an organic insulating material, but embodiments of the present disclosure are not limited thereto. The third optical layer 117c can be formed of the same material as the first optical layer 117a, but embodiments of the present disclosure are not limited thereto. For example, the first optical layer 117a can include fine particles, and the third optical layer 117c need not include fine particles. For example, the third optical layer 117c can be made of siloxane, but embodiments of the present disclosure are not limited thereto.

For example, the thickness of the first optical layer 117a can be less than the thickness of the third optical layer 117c, but embodiments of the present disclosure are not limited thereto. Accordingly, when viewed from a plan, the region in which the first optical layer 117a is arranged can include a concave portion recessed inwardly from the upper surface of the third optical layer 117c.

According to the present disclosure, the second electrode CE2 can be arranged on the first optical layer 117a and the third optical layer 117c. For example, the second electrode CE2 can be electrically connected to the plurality of contact electrodes CCE through contact holes in the third optical layer 117c. For example, the second electrode CE2 can be arranged on the plurality of light-emitting elements ED. For example, the second electrode CE2 can include a transparent conductive oxide such as indium tin oxide (ITO) or indium zinc oxide (IZO), but embodiments of the present disclosure are not limited thereto. For example, the second electrode CE2 can be arranged in contact with a cathode electrode 135. For example, the second electrode CE2 can overlap the first optical layer 117a. For example, the second electrode CE2 can cover the outer plane of the first optical layer 117a.

The second electrode CE2 can extend continuously in a first direction (X-axis direction) of the substrate 110. Accordingly, it can be commonly connected to the plurality of pixels PX arranged in the first direction (X-axis direction) of the substrate 110. For example, the second electrode CE2 can be commonly connected to the plurality of pixels PX.

According to the present disclosure, the second electrode CE2 can extend continuously on the first optical layer 117a, the third optical layer 117c, and the light-emitting element ED. The region in which the first optical layer 117a is arranged can include a concave portion that is recessed inwardly from the upper surface of the third optical layer 117c. Accordingly, the first portion of the second electrode CE2 arranged on the first optical layer 117a can be arranged along the concave portion, such that it can be arranged at a lower position than the second portion of the second electrode CE2 arranged on the third optical layer 117c.

A second optical layer 117b can be arranged on the second electrode CE2. The second optical layer 117b can be arranged to overlap the plurality of light-emitting elements ED and the first optical layer 117a. The second optical layer 117b can be arranged over the second electrode CE2 and the plurality of light-emitting elements ED, thereby improving the mura that can occur in some of the plurality of light-emitting elements ED. For example, when a plurality of light-emitting elements ED are transferred to the substrate 110 of the display device 1000, regions of non-uniform spacing between the plurality of light-emitting elements ED can occur due to process variations. If the spacing between the plurality of light-emitting elements ED is uneven, the light emission area of each of the plurality of light-emitting elements ED can be arranged uneven, resulting in the mura visible to the user. Thus, by configuring the second optical layer 117b to diffuse light uniformly to the upper portion of the plurality of light-emitting elements ED, it is possible to reduce the light emitted from some of the light-emitting elements ED from being visually recognized as the mura. Therefore, the light emitted from the plurality of light-emitting elements ED by the second optical layer 117b is uniformly diffused and extracted to the outside of the display device 1000, thereby improving the luminance uniformity of the display device 1000.

The second optical layer 117b can be formed of an organic insulating material in which fine particles are dispersed, but embodiments of the present disclosure are not limited thereto. For example, the third optical layer 117b can be formed of siloxane dispersed with fine metal particles, such as titanium dioxide (TiO₂) particles, but embodiments of the present disclosure are not limited thereto. For example, the second optical layer 117b can be formed of the same material as the first optical layer 117a, but embodiments of the present disclosure are not limited thereto. For example, the second optical layer 117b can be a diffusion layer or an upper diffusion layer, but embodiments of the present disclosure are not limited thereto.

According to the present disclosure, light from the plurality of light-emitting elements ED can be scattered by fine particles dispersed in the second optical layer 117b and emitted to the outside of the display device 1000. The second optical layer 117b can uniformly mix light emitted from the plurality of light-emitting elements ED, thereby further improving the luminance uniformity of the display device 1000. Additionally, the light extraction efficiency of the display device 1000 can be improved by the scattered light from the plurality of fine particles, thereby allowing the display device 1000 to be driven at low power.

A second passivation layer 116b can be arranged on the first optical layer 117a. Alternatively, the second passivation layer 116b can be arranged on the second optical layer 117b. Alternatively, it can be arranged on the third optical layer 117c. For example, the second passivation layer 116b can be arranged in the display area AA and the first non-display area NA1. Since the second passivation layer 116b is arranged to cover the first optical layer 117a, the second optical layer 117b, or the third optical layer 117c arranged in the display area AA and the first non-display area NA1, the moisture or impurity ingress into the first optical layer 117a, the second optical layer 117b, or the third optical layer 117c can be reduced. For example, the second passivation layer 116b can be formed of a single or multiple layers of silicon oxide (SiOx) or silicon nitride (SiNx), but embodiments of the present disclosure are not limited thereto. For example, the second passivation layer 116b can be a protective layer or an insulating layer, but embodiments of the present disclosure are not limited thereto.

A black matrix BM can be arranged on the second electrode CE2, the first optical layer 117a, the third optical layer 117c, and the second optical layer 117b in the display area AA. For example, the black matrix BM can fill the contact holes in the third optical layer 117c. The black matrix BM can be configured to cover the display area AA, thereby reducing the color mixing of light from the plurality of sub-pixels and reflection of external light. For example, the black matrix BM can also be arranged within the contact holes in which the second electrode CE2 and the contact electrode CCE are connected, thereby preventing light leakage between the plurality of adjacent sub-pixels.

For example, the black matrix BM can be formed of an opaque material, but embodiments of the present disclosure are not limited thereto. For example, the black matrix BM can be a black pigment or an organic insulating material to which a black dye has been added, but embodiments of the present disclosure are not limited thereto.

In the display area AA, a cover layer 118 can be arranged on the black matrix BM. The cover layer 118 can protect the components under the cover layer 118. For example, the cover layer 118 can be formed of an organic insulating material, but embodiments of the present disclosure are not limited thereto. For example, the cover layer 118 can be formed of a photo resist, polyimide (PI), or photo acryl-based material, but embodiments of the present disclosure are not limited thereto. For example, the cover layer 118 can be an overcoating layer or an insulating layer, but embodiments of the present disclosure are not limited thereto.

The polarizing layer 293 can be arranged on the cover layer 118 via the first adhesive layer 291. The cover member 120 can be arranged on the polarizing layer 293 via the second adhesive layer 295. For example, the first adhesive layer 291 and the second adhesive layer 295 can include an optically clear adhesive (OCA), an optically clear resin (OCR), or a pressure sensitive adhesive (PSA), but embodiments of the present disclosure are not limited thereto.

According to the present disclosure, the plurality of pad electrodes PE can be arranged on the third insulating layer 115c in the second non-display area NA2. For example, at least a portion of the plurality of pad electrodes PE can be exposed from the passivation layer 116a. For example, the plurality of pad electrodes PE can be electrically connected to the second-fourth connection wires 122d through contact holes in the third insulating layer 115c.

An adhesive layer ACF can be arranged on the plurality of pad electrode PE. The adhesive layer ACF can be an adhesive layer in which conductive balls are dispersed in an insulating material, but embodiments of the present disclosure are not limited thereto. When heat or pressure is applied to the adhesive layer ACF, the conductive balls can become electrically connected and have conductive properties at the points where heat or pressure is applied, exhibiting the conductive properties. The adhesive layer ACF can be arranged between the plurality of pad electrodes PE and the flexible circuit board (or flexible film) CB to attach or bond the flexible circuit board (or flexible film) CB to the plurality of pad electrodes PE. For example, the adhesive layer ACF can be an anisotropic conductive film (ACF), but embodiments of the present disclosure are not limited thereto.

The flexible circuit board (or flexible film) CB can be arranged on the adhesive layer ACF. The flexible circuit board (or flexible film) CB can be electrically connected to the plurality of pad electrodes PE through the adhesive layer ACF. Thus, signals output from the flexible circuit board (or flexible film) CB and the printed circuit board can be transmitted to the pixel driving circuit PD of the display area AA through the plurality of pad electrodes PE, the second-fourth connection wire 122d, the second-third connection wire 122c, the second-second connection wire 122b, and the second-first connection wire 122a.

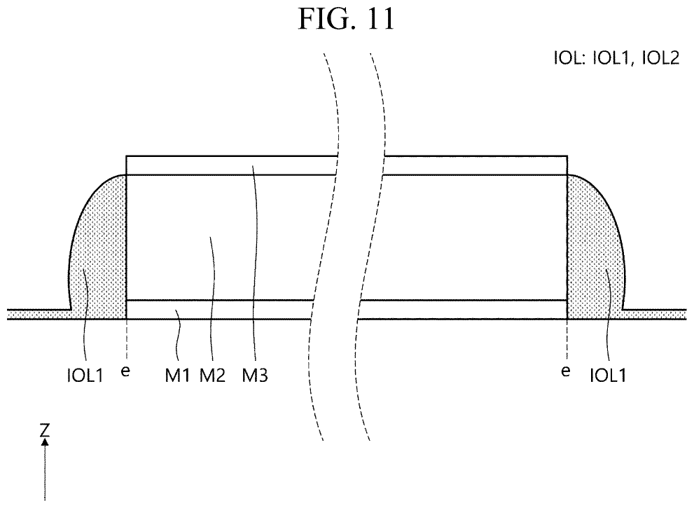

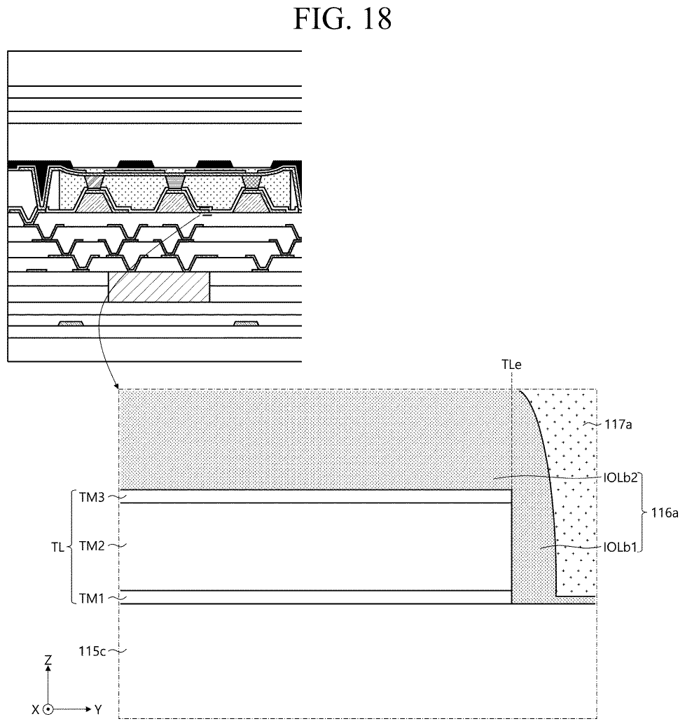

FIGS. 11 to 22 are cross-sectional views illustrating the display device according to an embodiment of the present disclosure.

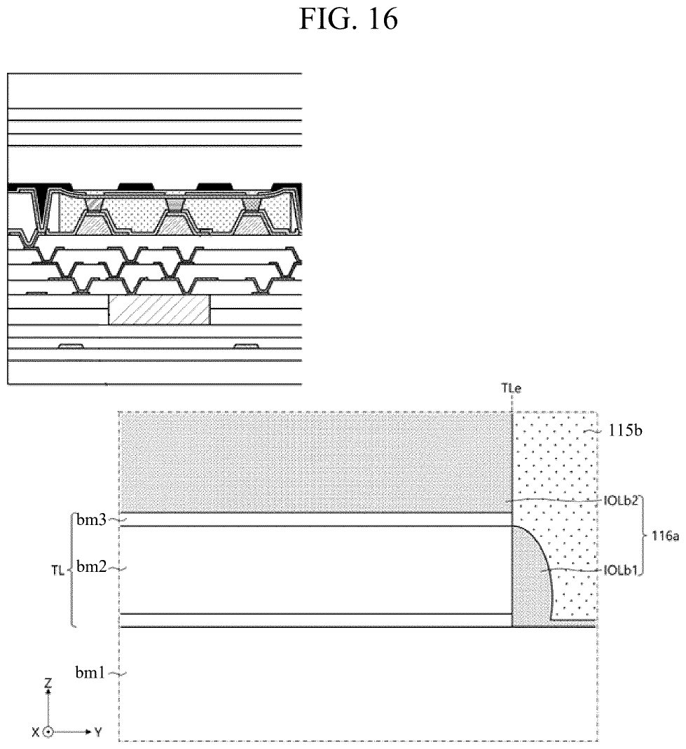

FIGS. 11 to 15 are diagrams, each illustrating a wire and a configuration for protecting the wire. FIGS. 16 to 22 are partially enlarged views illustrating an enlargement of end portions of multiple wires shown in FIG. 10. The same reference numbers are assigned to substantially the same configuration between the embodiments, and repeated descriptions are omitted.

Referring to FIG. 11, the display panel according to an embodiment of the present disclosure can include a first metal layer M1, a third metal layer M3 arranged on the first metal layer M1, and a second metal layer M2 arranged between the first metal layer M1 and the third metal layer M3. The second metal layer M2 can be arranged on the first metal layer M1, and the third metal layer M3 can be arranged on the second metal layer M2. Each of the first metal layer M1, the second metal layer M2, and the third metal layer M3 can be formed of molybdenum (Mo), chromium (Cr), titanium (Ti), nickel (Ni), neodymium (Nd), copper (Cu), aluminum (Al), and alloys of silver (Ag) and magnesium (Mg), a multi-layer stack-up of these materials, or alloys thereof, but embodiments of the present disclosure are not limited thereto. Alternatively, each of the first metal layer M1, the second metal layer M2, and the third metal layer M3 can be formed of a multi-layer stack-up of indium tin oxide (ITO)/titanium (Ti)/aluminum (Al)/titanium (Ti), but embodiments of the present disclosure are not limited thereto.

For example, the first metal layer M1 can be formed of the same material as the third metal layer M3, but embodiments of the present disclosure are not limited thereto. For example, the first metal layer M1, the second metal layer M2, and the third metal layer M3 can be formed from different materials.

A structure in which the first metal layer M1, the second metal layer M2, and the third metal layer M3 are stacked can include both ends ‘e’. As shown in the drawing, the both ends e can be formed so that the first metal layer M1, the second metal layer M2, and the third metal layer M3 all overlap in the thickness direction (for example, in the Z-axis direction) of the display panel. However, depending on the implementation, differences in the shape of the ends e can occur during the manufacturing process. For example, an end e of the first metal layer M1 and an end e of the second metal layer M2 need not overlap.

The thickness of the second metal layer M2 can be greater than the thickness of the first metal layer M1 or the third metal layer M3. The thickness of the first metal layer M1 can be the same as the thickness of the third metal layer M3. The thickness of the first metal layer M1 can be different from the thickness of the third metal layer M3. For example, the thickness of the first metal layer M1 can be greater than or equal to the thickness of the third metal layer M3.

In the structure in which the first metal layer M1, the second metal layer M2, and the third metal layer M3 are stacked, the end e of the first metal layer M1, the end e of the second metal layer M2, and the end e of the third metal layer M3 can be exposed outside the stacked structure of the metal layers. In the case where the thickness of the second metal layer M2 is greater than that of the first metal layer M1 or the third metal layer M3, the degree of exposure of the end e of the second metal layer M2 can be greater than that of the first metal layer M1 or the third metal layer M3.

As the length, size, or area exposed to the outside increases, the duration of exposure of the first metal layer M1, the second metal layer M2, and the third metal layer M3 to gas that they can contact during the manufacturing process can also increase. For example, the gas can be an etching gas used in an etching process. For example, the etching gas can be a dry etching gas.

For example, if the degree of exposure of the second metal layer M2 is greater than that of the first metal layer M1, the duration of exposure of the second metal layer M2 to gas can be longer than that of the first metal layer M1. As a result, the second metal layer M2 can be relatively more likely to be corroded by gas. For example, the second metal layer M2 can react with gas to produce a product, and moisture or the like can penetrate into the display panel containing the product to cause corrosion to proceed.

Embodiments of the present disclosure can reduce the likelihood of corrosion by arranging an inorganic layer IOL on the end e, thereby preventing the ends e of the first metal layer M1, the second metal layer M2, or the third metal layer M3 from being exposed to gas.

The inorganic layer IOL can include an inorganic layer IOL1 covering the end e.

The deposited inorganic layer IOL can be formed to cover the end e of the second metal layer M2. In addition, the inorganic layer can have a tapered shape in which the bottom widens by an etching process, which will be described later, from the second metal layer M2 towards the direction in which the first metal layer M1 is arranged, which will be described later. The border of the tapered shape can have a curvature. The deposited inorganic layer IOL can be formed to cover the ends e of the first metal layer M1 and the second metal layer M2. The inorganic layer can be formed to cover both ends e of each of the first metal layer M1 and the second metal layer M2.

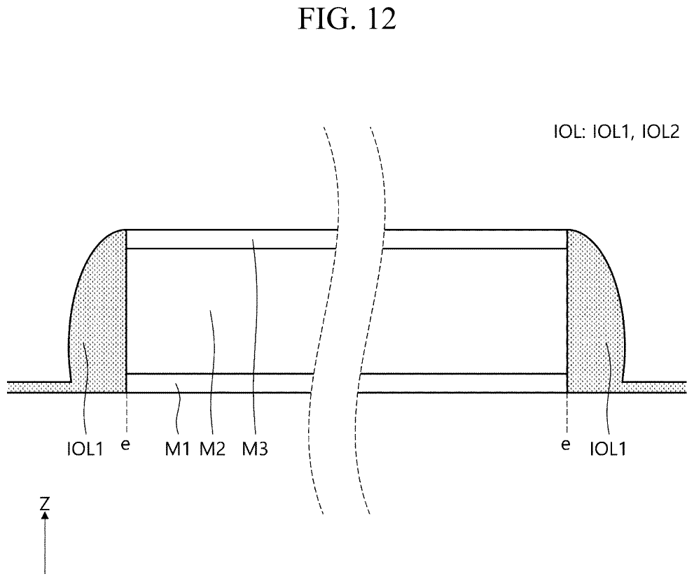

Referring to FIG. 12, the deposited inorganic layer IOL can be formed to cover the end e of the second metal layer M1. The inorganic layer IOL can have a tapered shape in which the bottom widens from the second metal layer M1 toward the direction in which the first metal layer M1 is arranged. The border of the tapered shape can have a curvature. The deposited inorganic layer IOL can be formed to cover the ends e of the first metal layer M1, the second metal layer M1, and the third metal layer M3. The inorganic layer IOL can be formed to cover both ends e of each of the first metal layer M1, the second metal layer M1, and the third metal layer M3.

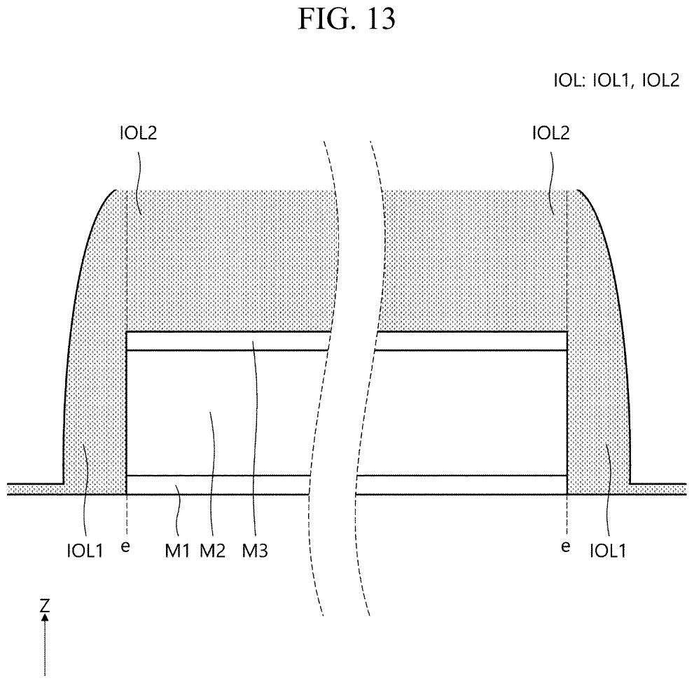

Referring to FIG. 13, the inorganic layer IOL can include an inorganic layer IOL1 covering the end e and an inorganic layer IOL2 covering the top of the third metal layer M3.

The deposited inorganic layer IOL can be formed to cover the end e of the second metal layer M2. Additionally, the inorganic layer IOL can have a tapered shape in which the bottom widens by an etching process, which will be described later, from the second metal layer M2 toward the direction in which the first metal layer M1 is arranged. The border of the tapered shape can have a curvature. The deposited inorganic layer IOL can be formed to cover the ends e of the first metal layer M1, the second metal layer M1, and the third metal layer M3. The inorganic layer IOL can be formed to cover both ends e of each of the first metal layer M1 and the second metal layer M1. The inorganic layer IOL can be arranged on the third metal layer M3. The inorganic layer IOL can be formed to cover the upper portion of the third metal layer M3.

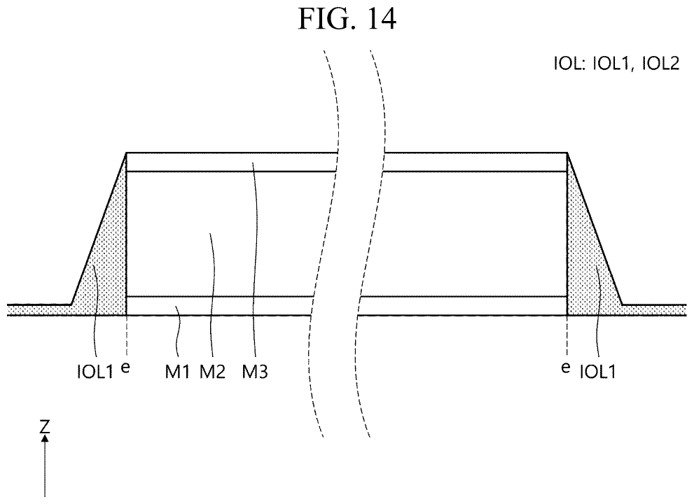

Referring to FIG. 14, the deposited inorganic layer IOL can be formed to cover the end e of the second metal layer M1. The inorganic layer IOL can have a tapered shape in which the bottom widens from the second metal layer M1 toward the direction in which the first metal layer M1 is arranged. The deposited inorganic layer IOL can be formed to cover the ends e of the first metal layer M1, the second metal layer M1, and the third metal layer M3. The inorganic layer IOL can be formed to cover both ends e of each of the first metal layer M1, the second metal layer M1, and the third metal layer M3.

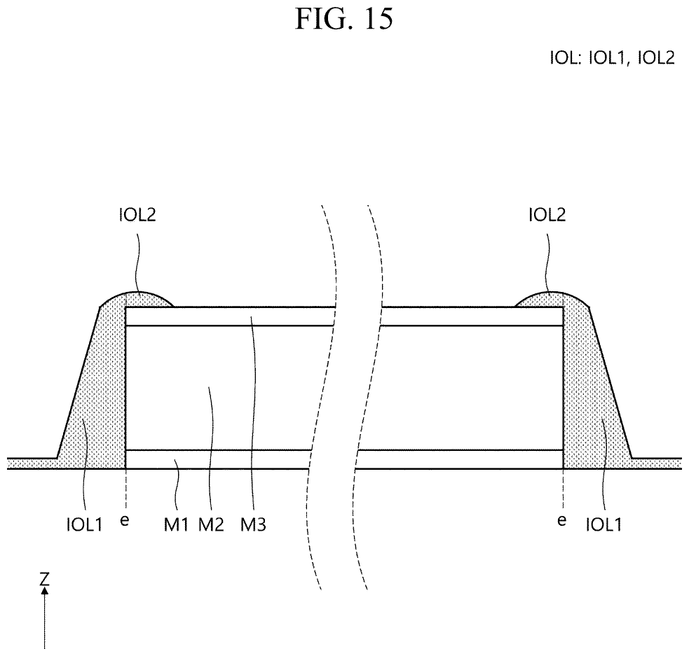

Referring to FIG. 15, the inorganic layer IOL can include an inorganic layer IOL1 covering the ends e and an inorganic layer IOL2 covering the top of the third metal layer M3.

The deposited inorganic layer IOL can be formed to cover the end e of the second metal layer M2. In addition, the inorganic layer can have a tapered shape in which the bottom widens by an etching process, which will be described later, from the second metal layer M2 towards the direction in which the first metal layer M1 is arranged. The border of the tapered shape can have a curvature. The deposited inorganic layer IOL can be formed to cover the ends e of the first metal layer M1, the second metal layer M1, and the third metal layer M3. The inorganic layer IOL can be formed to cover both ends e of each of the first metal layer M1 and the second metal layer M1. The inorganic layer IOL can be arranged on the third metal layer M3. The inorganic layer IOL can be formed to cover at least a portion of the upper portion of the third metal layer M3.

FIG. 16 is a partially enlarged view illustrating an enlargement of the end portion of the first-second connection wire described above.

Referring to FIGS. 10 and 16, the first-second connection wire 121b can be arranged on the first-first connection wire 121a. The first-second connection wire 121b can include a first metal layer bM1, a second metal layer bM2 arranged on the first metal layer bM1, and a third metal layer bM3 arranged on the second metal layer bM2. Each of the metal layers bM1, bM2, and bM3 can correspond to the first metal layer M1, the second metal layer M2, and the third metal layer M3 described above. For example, each of the first metal layer bM1, the second metal layer bM2, and the third metal layer bM3 can be formed of molybdenum (Mo), chromium (Cr), titanium (Ti), nickel (Ni), neodymium (Nd), copper (Cu), aluminum (Al), and alloys of silver (Ag) and magnesium (Mg), or a multi-layer stack-up of these materials, or alloys thereof, but embodiments herein are not limited thereto. Alternatively, each of the first metal layer bM1, the second metal layer bM2, and the third metal layer bM3 can be formed of a multi-layer stack-up of indium tin oxide (ITO)/titanium (Ti)/aluminum (Al)/titanium (Ti), but embodiments of the present disclosure are not limited thereto.

The first-second connection wire 121b can include an end 121be. The end 121be of the first-second connection wire 121b can correspond to the end e described above. The end of the first metal layer bM1 of the first-second connection wire 121b, the end of the second metal layer bM2 of the first-second connection wire 121b, and the end of the third metal layer bM3 of the first-second connection wire 121b can overlap each other in the thickness direction of the display panel (e.g., the Z-axis direction) as shown, but embodiments according to the present disclosure are not limited thereto.

The first metal layer bM1 of the first-second connection wire 121b, the second metal layer bM2 of the first-second connection wire 121b, and/or the third metal layer bM3 of the first-second connection wire 121b can be arranged between the third protective layer 114 and the first insulating layer 115a.

A first inorganic layer IOLa can be arranged between the third protective layer 114 and the first insulating layer 115a. The first inorganic layer IOLa can include a first-first inorganic layer IOLa1 covering the end of the second metal layer bM2 of the first-second connection wire 121b. The first-first inorganic layer IOLa1 can cover the end of the third metal layer bM3. The first inorganic layer IOLa can include a first-second inorganic layer IOLa2 arranged on the third metal layer bM3 of the first-second connection wire 121b. The first inorganic layer IOLa can correspond to the inorganic layer IOL described above. The first-first inorganic layer IOLa1 can have a tapered shape. The border of the first-first inorganic layer IOLa1 can have a curvature. The second metal layer bM2 of the first-second connection wire 121b can be protected from gas by the first-first inorganic layer IOLa1. Additionally, the first-first inorganic layer IOLa1 can protect the first-second connection wire 121b from the ingress of particles, such as moisture, from the outside during the operation of the display device. Accordingly, the operational reliability of the display device can be improved and the lifespan of the display device can be extended. In various embodiments of the present disclosure, the first inorganic layer IOLa and/or the first insulating layer 115a can be referred to as a protective layer.

The thickness of the third metal layer bM3 of the first-second connection wire 121b can be 150% to 300% of the thickness of the first metal layer bM1 of the first-second connection wire 121b. Alternatively, it can be 175% to 250%. The thickness of the second metal layer bM2 of the first-second connection wire 121b can be 1100% to 1400% of the thickness of the third metal layer bM3 of the first-second connection wire 121b. Alternatively, it can be 1200% to 1300%. Considering the thickness of the first-second connection wire 121b described above, the first-first inorganic layer IOLa1 can be formed relatively thick, but embodiments of the present disclosure are not limited thereto.

Also, with reference to FIGS. 11-16, the first inorganic layer IOLa can include a planar portion that extends away from the IOLa and is planar on an underlying layer. The planar portion of the first inorganic layer IOLa can be parallel to the first metal layer M1. In various embodiments of the present disclosure, a thickness of the planar portion of the first inorganic layer IOLa can be the same or different from that of the first metal layer M1. In various embodiments of the present disclosure, the planar portion of the first inorganic layer IOLa can be thinner than that of the first metal layer M1, but can also be thicker.

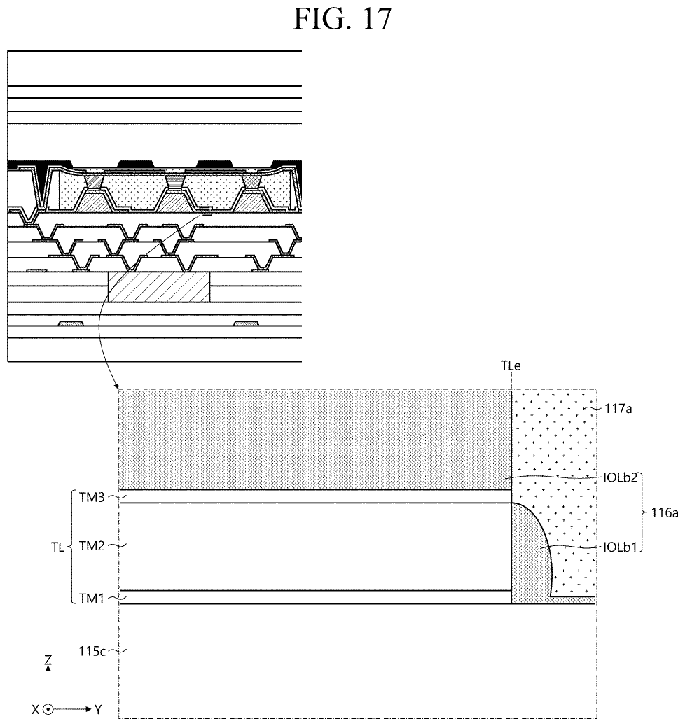

FIGS. 17 to 19 are partially enlarged views illustrating an enlargement of the end of the signal wire described above.

Referring to FIG. 10 and FIGS. 17 to 19, the signal wire TL can be arranged on the first-fourth connection wire 121d. The signal wire TL can include a first metal layer TM1, a second metal layer TM2 arranged on the first metal layer TM1, and a third metal layer TM3 arranged on the second metal layer TM2. Each of the metal layers TM1, TM2, and TM3 can correspond to the first metal layer M1, the second metal layer M2, and the third metal layer M3 described above. For example, each of the first metal layer TM1, the second metal layer TM2, and the third metal layer TM3 can be formed of molybdenum (Mo), chromium (Cr), titanium (Ti), nickel (Ni), neodymium (Nd), copper (Cu), aluminum (Al), and alloys of silver (Ag) and magnesium (Mg), or a multi-layer stack-up of these materials, or alloys thereof, but embodiments herein are not limited thereto. Alternatively, each of the first metal layer TM1, the second metal layer TM2, and the third metal layer TM3 can be formed of a multi-layer stack-up of indium tin oxide (ITO)/titanium (Ti)/aluminum (Al)/titanium (Ti), but embodiments of the present disclosure are not limited thereto.

The signal wire TL can include an end TLe. The end TLe of the signal wire TL can correspond to the end e described above. The end of the first metal layer TM1 of the signal wire TL, the end of the second metal layer TM2 of the signal wire TL, and the end of the third metal layer TM3 of the signal wire TL can overlap each other in the thickness direction (e.g., the Z-axis direction) of the display panel as shown, but embodiments according to the present disclosure are not limited thereto.

The first metal layer TM1 of the signal wire TL, the second metal layer TM2 of the signal wire TL, and/or the third metal layer TM3 of the signal wire TL can be arranged between the third insulating layer 115c and the first optical layer 117a.

The first passivation layer 116a can be arranged between the third insulating layer 115c and the first optical layer 117a. The first passivation layer 116a can be a second inorganic layer. The first passivation layer 116a can include a second-first inorganic layer IOLb1 covering the end of the second metal layer TM2 of the signal wire TL. The second-first inorganic layer IOLb1 can cover the end of the third metal layer TM3. The first passivation layer 116a can include a second-second inorganic layer IOLb2 arranged on the third metal layer TM3 of the signal wire TL. The first passivation layer 116a can correspond to the inorganic layer IOL described above. The second-first inorganic layer IOLb1 can have a tapered shape. The border of the second-first inorganic layer IOLb1 can have a curvature. The second metal layer TM2 of the signal wire TL can be protected from gas by the second-first inorganic layer IOLb1. Additionally, the second inorganic layer IOLb1 can protect the signal wire TL from the ingress of particles, such as moisture, from the outside during the operation of the display device. Accordingly, the operational reliability of the display device can be improved and the lifespan of the display device can be extended.

The thickness of the third metal layer TM3 of the signal wire TL can be from 50% to 150% of the thickness of the first metal layer TM1 of the signal wire TL. Alternatively, it can be 75% to 125%. The thickness of the second metal layer TM2 of the signal wire TL can be 550% to 650% of the thickness of the third metal layer TM3 of the signal wire TL. Alternatively, it can be 575% to 625%. Considering the thickness of the signal wire TL described above, the second-first inorganic layer IOLb1 can be formed relatively thin, but embodiments of the present disclosure are not limited thereto.

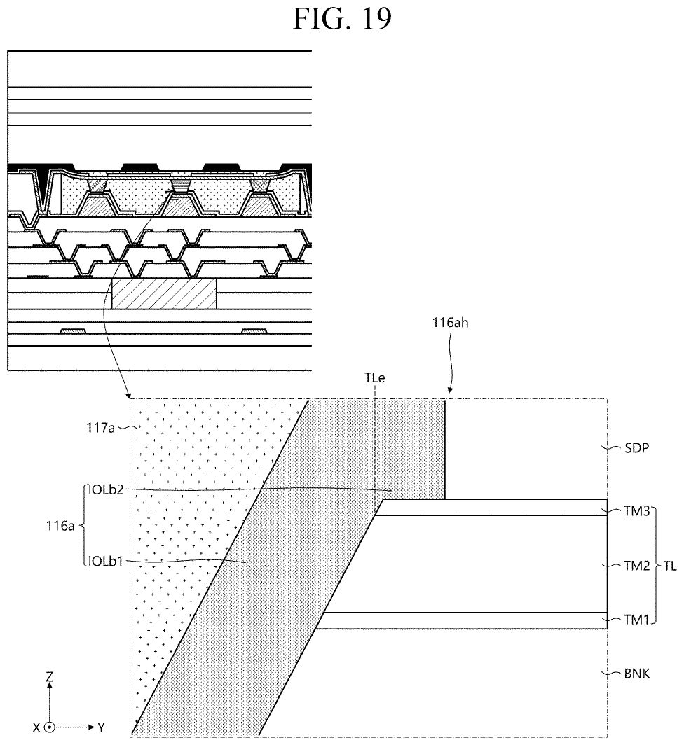

Referring to FIGS. 10 and 19, the other end TLe of the signal wire TL can be arranged between the bank BNK and the solder pattern SDP. The first passivation layer 116a can be formed to correspond to the border shape of the bank BNK and the signal wire TL. The space in which the solder pattern SDP is formed can correspond to a hole 116ah in the first passivation layer 116a.

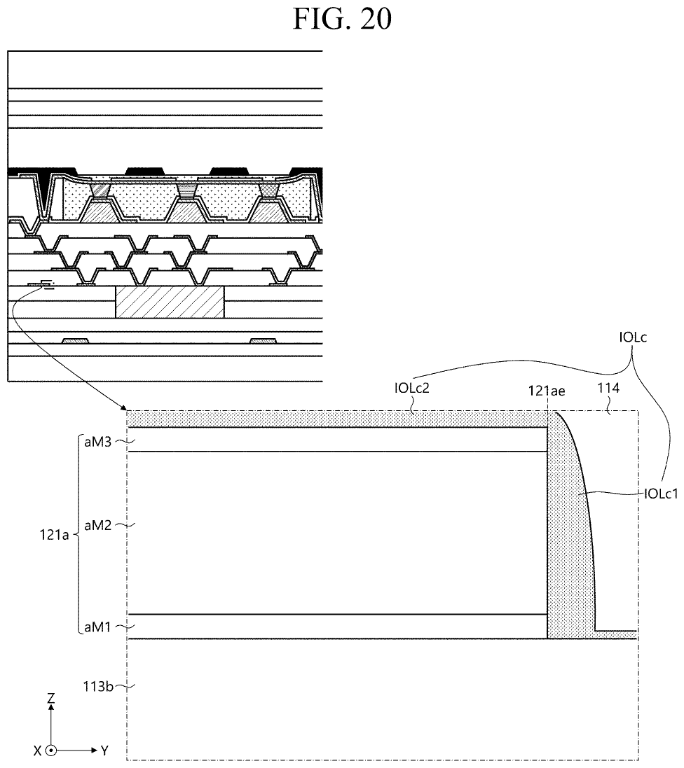

FIG. 20 is a partially enlarged view illustrating an enlargement of the end of the first-first connection wire described above.

Referring to FIGS. 10 and 20, the first-first connection wire 121a can be arranged on the second protective layer 131b. The first-first connection wire 121a can include a first metal layer aM1, a second metal layer aM2 arranged on the first metal layer aM1, and a third metal layer aM3 arranged on the second metal layer aM2. Each of the metal layers aM1, aM2, and aM3 can correspond to the first metal layer M1, the second metal layer M2, and the third metal layer M3 described above. For example, each of the first metal layer aM1, the second metal layer aM2, and the third metal layer aM3 can be formed of molybdenum (Mo), chromium (Cr), titanium (Ti), nickel (Ni), neodymium (Nd), copper (Cu), aluminum (Al), and alloys of silver (Ag) and magnesium (Mg), or a multi-layer stack-up of these materials, or alloys thereof, but embodiments herein are not limited thereto. Alternatively, each of the first metal layer aM1, the second metal layer aM2, and the third metal layer aM3 can be formed of a multi-layer stack-up of indium tin oxide (ITO)/titanium (Ti)/aluminum (Al)/titanium (Ti), but embodiments of the present disclosure are not limited thereto.

The first-first connection wire 121a can include an end 121ae. The end 121ae of the first-first connection wire 121a can correspond to the end e described above. The end of the first metal layer aM1 of the first-first connection wire 121a, the end of the second metal layer aM2 of the first-first connection wire 121a, and the end of the third metal layer aM3 of the first-first connection wire 121a can overlap each other in the thickness direction of the display panel (e.g., the Z-axis direction) as shown, but embodiments according to the present disclosure are not limited thereto.

The first metal layer aM1 of the first-first connection wire 121a, the second metal layer aM2 of the first-first connection wire 121a, and/or the third metal layer aM3 of the first-first connection wire 121a can be arranged between the second protective layer 113b and the third protective layer 114.

A third inorganic layer IOLc can be arranged between the second protective layer 113b and the third protective layer 114. The third inorganic layer IOLc can include a third-first inorganic layer IOLc1 covering the end of the second metal layer aM2 of the first-first connection wire 121a. The third-first inorganic layer IOLc1 can cover the end of the third metal layer aM3. The third inorganic layer IOLc can include a third-second inorganic layer IOLc2 arranged on the third metal layer aM3 of the first-first connection wire 121a. The third inorganic layer IOLc can correspond to any of the inorganic layers IOL described above. The third-first inorganic layer IOLc1 can have a tapered shape. The border of the third-first inorganic layer IOLc1 can have a curvature. The second metal layer aM2 of the first-first connection wire 121a can be protected from gas by the third-first inorganic layer IOLc1. In addition, the third-first inorganic layer IOLc1 can protect the first-first connection wire 121a from the ingress of particles, such as moisture, from the outside during the operation of the display device. Accordingly, the operational reliability of the display device can be improved and the lifespan of the display device can be extended.

The thickness of the third metal layer aM3 of the first-first connection wire 121a can be from 150% to 300% of the thickness of the first metal layer aM1 of the first-first connection wire 121a. Alternatively, it can be 175% to 250%. The thickness of the second metal layer aM2 of the first-first connection wire 121a can be 1100% to 1400% of the thickness of the third metal layer aM3 of the first-first connection wire 121a. Alternatively, it can be 1200% to 1300%. Considering the thickness of the first-first connection wire 121a described above, the third-first inorganic layer IOLc1 can be formed relatively thick, but embodiments of the present disclosure are not limited thereto.

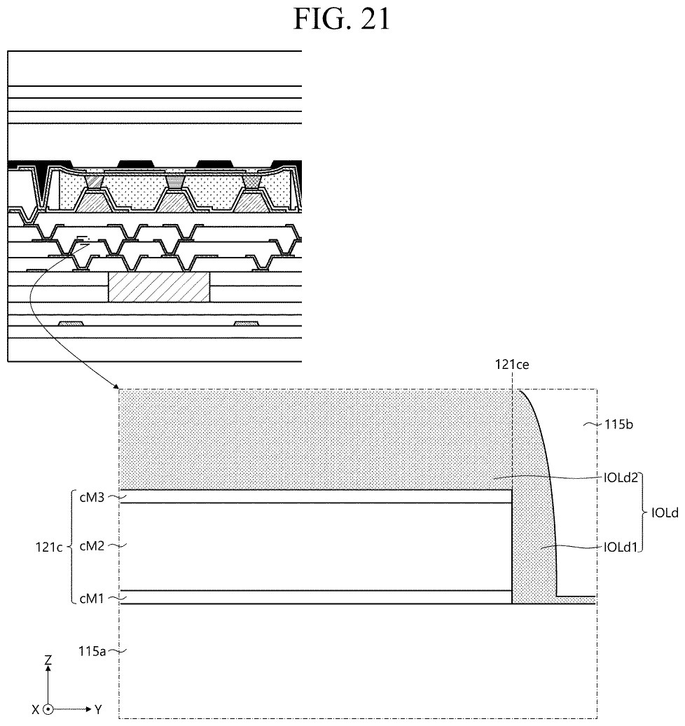

FIG. 21 is a partially enlarged view illustrating an enlargement of the end of the first-third connection wire described above.

Referring to FIGS. 10 and 21, the first-third connection wire 121c can be arranged on the first insulating layer 115a. The first-third connection wire 121c can include a first metal layer cM1, a second metal layer cM2 arranged on the first metal layer cM1, and a third metal layer cM3 arranged on the second metal layer cM2. Each of the metal layers cM1, cM2, and cM3 can correspond to the first metal layer M1, the second metal layer M2, and the third metal layer M3 described above. For example, each of the first metal layer cM1, the second metal layer cM2, and the third metal layer cM3 can be formed of molybdenum (Mo), chromium (Cr), titanium (Ti), nickel (Ni), neodymium (Nd), copper (Cu), aluminum (Al), and alloys of silver (Ag) and magnesium (Mg), or a multi-layer stack-up of these materials, or alloys thereof, but embodiments herein are not limited thereto. Alternatively, each of the first metal layer cM1, the second metal layer cM2, and the third metal layer cM3 can be formed of a multi-layer stack-up of indium tin oxide (ITO)/titanium (Ti)/aluminum (Al)/titanium (Ti), but embodiments of the present disclosure are not limited thereto.

The first-third connection wire 121c can include an end 121ce. The end 121ce of the first-third connection wire 121c can correspond to the end e described above. The end of the first metal layer cM1 of the first-third connection wire 121c, the end of the second metal layer cM2 of the first-third connection wire 121c, and the end of the third metal layer cM3 of the first-third connection wire 121c can overlap each other in the thickness direction (e.g., the z-axis direction) of the display panel as shown, but embodiments according to the present disclosure are not limited thereto.

The first metal layer cM1 of the first-third connection wire 121c, the second metal layer cM2 of the first-third connection wire 121c, and/or the third metal layer cM3 of the first-third connection wire 121c can be arranged between the first insulating layer 115a and the second insulating layer 115b.

A fourth inorganic layer IOLd can be disposed between the first insulating layer 115a and the second insulating layer 115b. The fourth inorganic layer IOLd can include a fourth-first inorganic layer IOLd1 covering the end of the second metal layer cM2 of the first-third connection wire 121c. The fourth-first inorganic layer IOLd1 can cover the end of the third metal layer cM3. The fourth inorganic layer IOLd can include a fourth-second inorganic layer IOLd2 arranged on the third metal layer cM3 of the first-third connection wire 121c. The fourth inorganic layer IOLd can correspond to any of the inorganic layers IOL described above. The fourth-first inorganic layer IOLd1 can have a tapered shape. The border of the fourth-first inorganic layer IOLd1 can have a curvature. The second metal layer cM2 of the first-third connection wire 121c can be protected from gas by the fourth-first inorganic layer IOLd1. Additionally, the fourth-first inorganic layer IOLd1 can protect the first-third connection wire 121c from the ingress of particles, such as moisture, from the outside during the operation of the display device. Accordingly, the operational reliability of the display device can be improved and the lifespan of the display device can be extended.

The thickness of the third metal layer cM3 of the first-third connection wire 121c can be from 50% to 150% of the thickness of the first metal layer cM1 of the first-third connection wire 121c. Alternatively, it can be 75% to 125%. The thickness of the second metal layer cM2 of the first-third connection wire 121c can be 550% to 650% of the thickness of the third metal layer cM3 of the first-third connection wire 121c. Alternatively, it can be 575% to 625%. Considering the thickness of the first-third connection wires 121c described above, the fourth-first inorganic layer IOLd1 can be formed relatively thin, but embodiments of the present disclosure are not limited thereto.

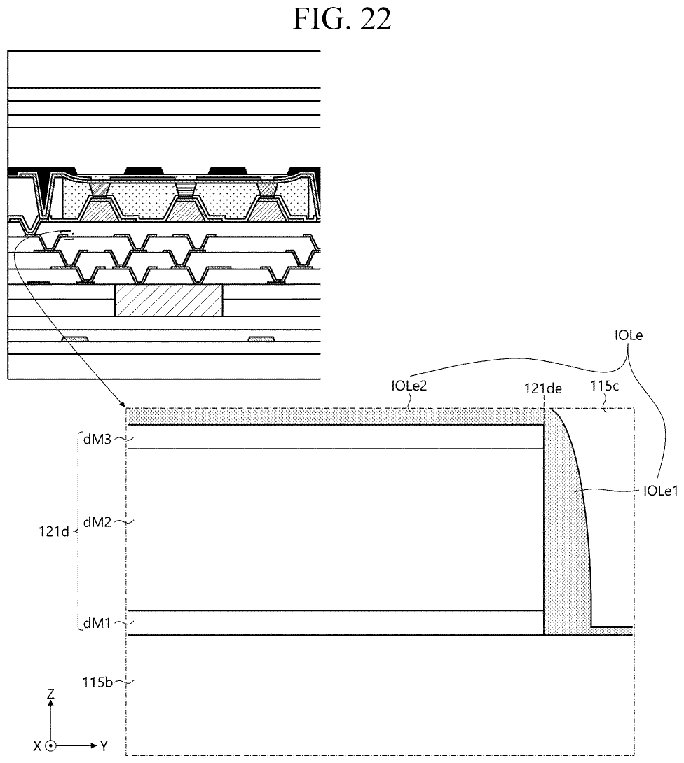

FIG. 22 is a partially enlarged view illustrating an enlargement of the end of the first-fourth connection wire described above.

Referring to FIGS. 10 and 22, the first-fourth connection wire 121d can be arranged on the second insulating layer 115b. The first-fourth connection wire 121d can include a first metal layer dM1, a second metal layer dM2 arranged on the first metal layer dM1, and a third metal layer dM3 arranged on the second metal layer dM2. Each of the metal layers dM1, dM2, and dM3 can correspond to the first metal layer M1, the second metal layer M2, and the third metal layer M3 described above. For example, each of the first metal layer dM1, the second metal layer dM2, and the third metal layer dM3 can be formed of molybdenum (Mo), chromium (Cr), titanium (Ti), nickel (Ni), neodymium (Nd), copper (Cu), aluminum (Al), and alloys of silver (Ag) and magnesium (Mg), or a multi-layer stack-up of these materials, or alloys thereof, but embodiments herein are not limited thereto. Alternatively, each of the first metal layer dM1, the second metal layer dM2, and the third metal layer dM3 can be formed of a multi-layer stack-up of indium tin oxide (ITO)/titanium (Ti)/aluminum (Al)/titanium (Ti), but embodiments of the present disclosure are not limited thereto.

The first-fourth connection wire 121d can include an end 121de. The end 121de of the first-fourth connection wire 121d can correspond to the end e described above. The end of the first metal layer dM1 of the first-fourth connection wire 121d, the end of the second metal layer dM2 of the first-fourth connection wire 121d, and the end of the third metal layer dM3 of the first-fourth connection wire 121d can overlap each other in the thickness direction (e.g., the z-axis direction) of the display panel as shown, but embodiments according to the present disclosure are not limited thereto.

The first metal layer dM1 of the first-fourth connection wire 121d, the second metal layer dM2 of the first-fourth connection wire 121d, and/or the third metal layer dM3 of the first-fourth connection wire 121d can be arranged between the second insulating layer 115b and the third insulating layer 115c.

A fifth inorganic layer IOLe can be disposed between the second insulating layer 115b and the third insulating layer 115c. The fifth inorganic layer IOLe can include a fifth-first inorganic layer IOLe1 covering the end of the second metal layer dM2 of the first-fourth connection wire 121d. The fifth-first inorganic layer IOLe1 can cover the end of the third metal layer dM3. The fifth inorganic layer IOLe can include a fifth-second inorganic layer IOLe2 arranged on the third metal layer dM3 of the first-fourth connection wire 121d. The fifth inorganic layer IOLe can correspond to any of the inorganic layers IOL described above. The fifth-first inorganic layer IOLe1 can have a tapered shape. The border of the fifth-first inorganic layer IOLe1 can have a curvature. The second metal layer dM2 of the first-fourth connection wire 121d can be protected from gas by the fifth-first inorganic layer IOLe1. Additionally, the fifth-first inorganic layer IOLe1 can protect the first-fourth connection wire 121d from the ingress of particles, such as moisture, from the outside during the operation of the display device. Accordingly, the operational reliability of the display device can be improved and the lifespan of the display device can be extended.

The thickness of the third metal layer dM3 of the first-fourth connection wire 121d can be 150% to 300% of the thickness of the first metal layer dM1 of the first-fourth connection wire 121d. Alternatively, it can be 175% to 250%. The thickness of the second metal layer dM2 of the first-fourth connection wire 121d can be 1100% to 1400% of the thickness of the third metal layer dM3 of the first-fourth connection wire 121d. Alternatively, it can be 1200% to 1300%. Considering the thickness of the first-fourth connection wire 121d described above, the fifth-first inorganic layer IOLe1 can be formed relatively thick, but embodiments of the present disclosure are not limited thereto.

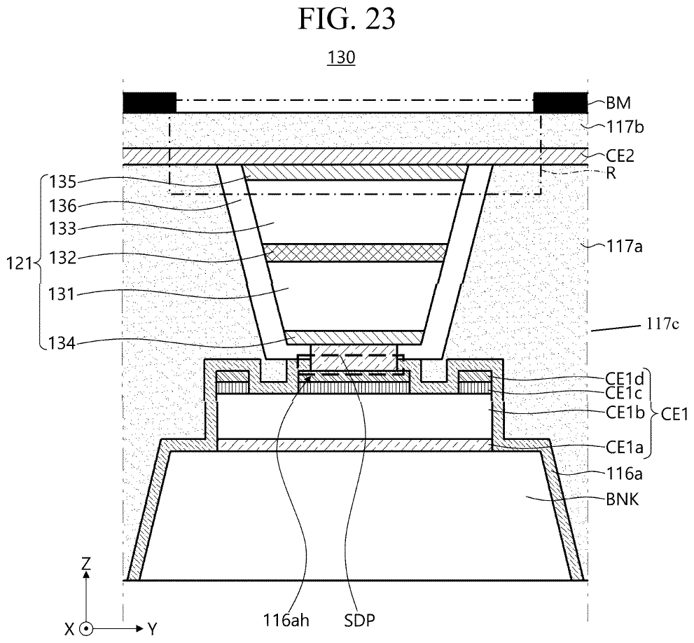

FIG. 23 is a cross-sectional view illustrating the display device according to an embodiment of the present disclosure.

Referring to FIGS. 23, the first electrode CE1 can be composed of a plurality of conductive layers. For example, the first electrode CE1 can include a first conductive layer CE1a, a second conductive layer CE1b, a third conductive layer CE1c, and a fourth conductive layer CE1d, but embodiments of the present disclosure are not limited thereto.

The first conductive layer CE1a can be arranged on the bank BNK. The second conductive layer CE1b can be arranged on the first conductive layer CE1a. The third conductive layer CE1c can be arranged on the second conductive layer CE1b. The fourth conductive layer CE1d can be arranged on the third conductive layer CE1c. For example, each of the first conductive layer CE1a, second conductive layer CE1b, third conductive layer CE1c, and fourth conductive layer CE1d can be formed of Titanium (Ti), Molybdenum (Mo), Aluminum (Al), or Titanium (Ti), and Indium Tin Oxide (ITO), but embodiments of the present disclosure are not limited thereto.

According to the present disclosure, some of the plurality of conductive layers constituting the first electrode CE1 and having good reflection efficiency can be configured as alignment keys and/or reflectors for aligning the light-emitting element ED. For example, the second conductive layer CE1b of the plurality of conductive layers of the first electrode CE1 can include a reflective material. For example, the second conductive layer CE1b can include aluminum (Al), but embodiments of the present disclosure are not limited thereto. In this way, the second conductive layer CE1b can be configured as a reflector. Additionally, the high reflection efficiency of the second conductive layer CE1b can facilitate easy identification during the manufacturing process, allowing for alignment of the position of the light-emitting element ED or its transfer position relative to the second conductive layer CE1b.

For example, in order to configure the second conductive layer CE1b as a reflector, the third conductive layer CE1c and the fourth conductive layer CE1d covering the second conductive layer CE1b can be partially removed or etched away. For example, portions of the third conductive layer CE1c and fourth conductive layer CE1d arranged on the bank BNK can be partially removed or etched to expose the top surface of the second conductive layer CE1b. For example, in the third conductive layer CE1c and the fourth conductive layer CE1d, the center portion and the border portions (or edge portions) where the solder pattern SDP is disposed are retained, while the remaining portions can be removed. For example, the border portion (or edge portion) of each of the third conductive layer CE1c made of titanium (Ti) and the fourth conductive layer CE1d made of indium tin oxide (ITO) need not be etched. Accordingly, the other conductive layers of the first electrode CE1 can be prevented from being corroded by the TMAH (TetraMethylAmmoniumHydroxide) solution used in the masking process of the first electrode CE1.

According to the present disclosure, the first conductive layer CE1a and the third conductive layer CE1c can contain titanium (Ti) or molybdenum (Mo). The second conductive layer CE1b can contain aluminum (Al). The fourth conductive layer CE1d can include a transparent conductive oxide layer such as indium tin oxide (ITO) or indium zinc oxide (IZO) which has good adhesion to the solder pattern SDP and has corrosion resistance and acid resistance. However, embodiments of the present disclosure are not limited thereto.

The first conductive layer CE1a, the second conductive layer CE1b, the third conductive layer CE1c, and the fourth conductive layer CE1d can be sequentially deposited and then patterned by a photolithography process and an etching process, but embodiments of the present disclosure are not limited thereto.

According to the present disclosure, the signal line TL, the contact electrode CCE, and the pad electrode PE arranged in the same layer as the first electrode CE1 can be formed of a multi-layer of a conductive material, but embodiments of the present disclosure are not limited thereto. For example, the signal line TL, the contact electrode CCE, and the pad electrode PE can be formed a multi-layer stack-up of indium tin oxide (ITO)/titanium (Ti)/aluminum (Al)/titanium (Ti), but embodiments of the present disclosure are not limited thereto.

According to the present disclosure, the solder pattern SDP can be arranged on the first electrode CE1 in each of the plurality of sub-pixels. The solder pattern SDP can bond the light-emitting element ED to the first electrode CE1. The first electrode CE1 and the light-emitting element ED can be electrically connected each other through eutectic bonding using the solder pattern SDP, but embodiments of the present disclosure are not limited thereto. The first electrode CE1 and the anode electrode 134 of the light-emitting element ED can be electrically connected through eutectic bonding using the solder pattern SDP, but embodiments of the present disclosure are not limited thereto. For example, if the solder pattern SDP is formed of indium (In) and the anode electrode 134 of the light-emitting element ED is formed of gold (Au), the solder pattern SDP and the anode electrode 134 can be bonded by applying heat and pressure during the transfer process of the light-emitting element ED. The eutectic bonding can allow the light-emitting element ED to be bonded to the solder pattern SDP and the first electrode CE1 without a separate adhesives. For example, the solder pattern SDP can be formed of indium (In), tin (Sn), or an alloy thereof, but embodiments of the present disclosure are not limited thereto. For example, the solder pattern SDP can be a bonding pad, or a binding pad, but embodiments of the present disclosure are not limited thereto.

According to the present disclosure, the first passivation layer 116a can be arranged on the plurality of signal wires TL, the plurality of first electrodes CE1, the plurality of contact electrodes CCE, and the third insulating layer 115c. For example, the first passivation layer 116a can be arranged in the display area AA, the first non-display area NA1, and the second non-display area NA2. A portion of the first passivation layer 116a arranged in the bending area BA can be removed. A portion of the first passivation layer 116a covering the plurality of pad electrodes PE in the second non-display area NA2 can be removed. The first passivation layer 116a can be arranged to cover the remaining area except the area in which the bending area BA, the plurality of pad electrodes PE, and the solder pattern SDP are arranged, thus reducing the ingress of moisture or impurities into the light-emitting element ED. For example, the first passivation layer 116a can be formed of a single or multiple layers of silicon oxide (SiOx) or silicon nitride (SiNx), but embodiments of the present disclosure are not limited thereto. For example, the first passivation layer 116a can be a protective layer or an insulating layer, but embodiments of the present disclosure are not limited thereto. For example, the passivation layer 116a can include a hole 116ah that exposes the solder pattern SDP.

The light-emitting element ED can be arranged on the solder pattern SDP in each of the plurality of sub-pixels. The first light-emitting element 130 can be arranged in the first sub-pixel SP1. The second light-emitting element 140 can be arranged in the second sub-pixel SP2. The third light-emitting element 150 can be arranged in the third sub-pixel SP3.

The light-emitting element ED can be formed on a silicon wafer by a method such as metal organic vapor deposition (MOCVD), chemical vapor deposition (CVD), plasma-enhanced chemical vapor deposition (PECVD), molecular beam growth (MBE), hydride vapor deposition (HVPE), or sputtering, but embodiments of the present disclosure are not limited thereto.

Referring to FIG. 23, the first light-emitting element 130 can include the anode electrode 134, a first semiconductor layer 131, an active layer 132, a second semiconductor layer 133, the cathode electrode 135, and an encapsulation film 136, but embodiments of the present disclosure are not limited thereto. For example, the encapsulation film 136 need not be included in the first light-emitting element 130.

The first semiconductor layer 131 can be arranged on the solder pattern SDP. The second semiconductor layer 133 can be arranged on the first semiconductor layer 131.

For example, one of the first semiconductor layer 131 and the second semiconductor layer 133 can be implemented as a compound semiconductor, such as a I-V group, II-VI group, or the like, and can be doped with impurities (or dopants). For example, one of the first semiconductor layer 131 and the second semiconductor layer 133 can be a semiconductor layer doped with n-type impurities, and the other can be a semiconductor layer doped with p-type impurities, but embodiments of the present disclosure are not limited thereto. For example, one or more of the first semiconductor layer 131 and the second semiconductor layer 133 can be a layer doped with n-type or p-type impurities on a material such as gallium nitride (GaN), gallium phosphide (GaP), aluminum gallium indium phosphide (AlGaInP), indium gallium nitride (AlGaN), aluminum indium nitride (AlInN), aluminum gallium nitride (AlInGaN), aluminum gallium gallium nitride (AlGaAs), aluminum gallium arsenide (AlGaAs), or gallium arsenide (GaAs), but embodiments of the present disclosure are not limited thereto. For example, the n-type impurity can be silicon (Si), germanium (Ge), selenium (Se), carbon (C), tellurium (Te), or tin (Sn), but embodiments of the present disclosure are not limited thereto. For example, the p-type impurity can be magnesium (Mg), zinc (Zn), calcium (Ca), strontium (Sr), barium (Ba), or beryllium (Be), but embodiments of the present disclosure are not limited thereto.

For example, the first semiconductor layer 131 and the second semiconductor layer 133 can be a nitride semiconductor containing n-type impurities and a nitride semiconductor containing p-type impurities, respectively, but embodiments of the present disclosure are not limited thereto. For example, the first semiconductor layer 131 can be a nitride semiconductor containing p-type impurities, and the second semiconductor layer 133 can be a nitride semiconductor containing n-type impurities, but embodiments of the present disclosure are not limited thereto.

The active layer 132 can be arranged between the first semiconductor layer 131 and the second semiconductor layer 133. The active layer 132 can emit light by receiving holes and electrons from the first semiconductor layer 131 and the second semiconductor layer 133. For example, the active layer 132 can be composed of one of a single well structure, a multi-well structure, a single quantum well structure, a multi-quantum well (MQW) structure, a quantum dot structure, and a quantum line structure, but embodiments of the present disclosure are not limited thereto. For example, the active layer 132 can be formed of indium gallium nitride (InGaN) or gallium nitride (GaN), but embodiments of the present disclosure are not limited thereto.

For another example, the active layer 132 can include a multi quantum well (MQW) structure having a well layer and a barrier layer with a higher band gap than the well layer. For example, the active layer 132 can be formed of InGaN as a well layer and AlGaN layer as a barrier layer, but embodiments of the present disclosure are not limited thereto.

The anode electrode 134 can be arranged between the first semiconductor layer 131 and the solder pattern SDP. For example, the anode electrode 134 can electrically connect the first semiconductor layer 131 and the first electrode CE1. The anode voltage output from the pixel driving circuit PD can be applied to the first semiconductor layer 131 through the signal wire TL, the first electrode CE1, and the anode electrode 134. For example, the anode electrode 134 can be formed of a conductive material that is capable of eutectic bonding with the solder pattern SDP, but embodiments of the present disclosure are not limited thereto. For example, the anode electrode 134 can be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or alloys thereof, but embodiments of the present disclosure are not limited thereto.

The cathode electrode 135 can be arranged on the second semiconductor layer 133. For example, the cathode electrode 135 can electrically connect the second semiconductor layer 133 and the second electrode CE2. The cathode voltage output from the pixel driving circuit PD can be applied to the second semiconductor layer 133 through the contact electrode CCE, the second electrode CE2, and the cathode electrode 135. The cathode electrode 135 can be formed of a transparent conductive material to allow light emitted from the light-emitting element to be directed toward the top of the light-emitting element, but embodiments of the present disclosure are not limited thereto. For example, the cathode electrode 135 can be formed of a material such as Indium Tin Oxide (ITO), Indium Zinc Oxide (IZO), or Indium Gallium Zinc Oxide (IGZO), but embodiments of the present disclosure are not limited thereto.

The encapsulation film 136 can be arranged on at least a portion of the first semiconductor layer 131, the active layer 132, the second semiconductor layer 133, the anode electrode 134, and the cathode electrode 135. For example, the encapsulation film 136 can surround at least a portion of the first semiconductor layer 131, the active layer 132, the second semiconductor layer 133, the anode electrode 134, and the cathode electrode 135.

For example, the encapsulation film 136 can protect the first semiconductor layer 131, the active layer 132, and the second semiconductor layer 133. For example, the encapsulation film 136 can be arranged on a side surface of the first semiconductor layer 131, a side surface of the active layer 132, and a side surface of the second semiconductor layer 133.

For example, the encapsulation film 136 can be arranged on at least portions of the anode electrode 134 and the cathode electrode 135, such as an edge portion (or one side) of the anode electrode 134 and an edge portion (or one side) of the cathode electrode 135. At least a portion of the anode electrode 134 can be exposed from the encapsulation film 136, allowing the anode electrode 134 and the solder pattern SDP to be connected. For example, at least a portion of the cathode electrode 135 can be exposed from the encapsulation film 136, allowing the cathode electrode 135 and the second electrode CE2 to be connected. For example, the encapsulation layer 136 can be formed of an insulating material such as silicon nitride (SiNx) or silicon oxide (SiOx), but embodiments of the present disclosure are not limited thereto.

For another example, the encapsulation film 136 can have a structure in which a reflective material is dispersed in a resin layer, but embodiments of the present disclosure are not limited thereto. For example, the encapsulation film 136 can be fabricated as a reflector of various structures, but embodiments of the present disclosure are not limited thereto. Light exciting from the active layer 132 by the encapsulation layer 136 is reflected upward to improve light extraction efficiency. For example, the encapsulation layer 136 can be a reflective layer, but embodiments of the present disclosure are not limited thereto.

Although the light-emitting element ED is described herein as having vertical structure, embodiments of the present disclosure are not limited thereto. For example, the light-emitting element ED can have a lateral structure or a flip chip structure.

While the first light-emitting element 130 has been described with reference to FIG. 23, the second light-emitting element 140 and third light-emitting element 150 can have substantially the same structure as the first light-emitting element 130. For example, the second light-emitting element 140 and the third light-emitting element 150 can be substantially the same as the first light-emitting element 130 having the first semiconductor layer 131, the active layer 132, the second semiconductor layer 133, the anode electrode 134, the cathode electrode 135, and the encapsulating film 136.

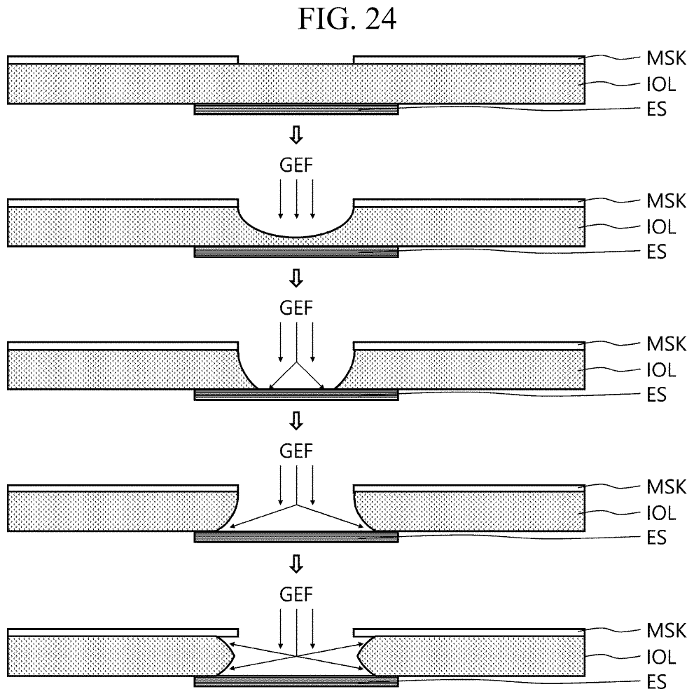

FIG. 24 is a diagram illustrating an etching process according to an embodiment of the present disclosure.

Referring to FIG. 24, a mask MSK can be arranged on one side of an inorganic/passivation layer IOL, and a protective/insulating layer ES can be arranged on the other side of the inorganic/passivation layer IOL. A circuit layer and an organic emission layer are arranged on the protection/insulating layer ES, but they are omitted for convenience of explanation. The mask MSK and the protective/insulating layer ES can be organic films that are applied or adhered to the inorganic/passivation layer IOL. The protective/insulating layer ES can act as an etch stopper during the etching process. The mask MSK can include an opening that exposes the inorganic/passivation layer IOL to a glass etching fluid GEF. The opening in the mask MSK can be formed by laser patterning. The shape, thickness, and spacing of the pattern to be formed in the inorganic/passivation layer IOL can be determined according to the shape, spacing, and etching process time of the opening. The mask MSK can be removed after the etching process. The inorganic/passivation layer IOL can be etched by spraying the glass etching fluid GEF onto the inorganic/passivation layer IOL to which the mask MSK is bonded, or by a dipping method.

The glass etching fluid GEF can be fed to the inorganic/passivation layer IOL through the opening in the mask MSK. The inorganic/passivation layer IOL exposed in the opening of the mask MSK can react with the glass etching fluid GEF and begin to etch.

A glass exposed to the etching fluid GEF is etched, forming an opening in the inorganic/passivation layer IOL, and the depth of the opening can become deeper as the etching process time elapses.

In the etching process, if the etching time is extended, the glass etching solution GEF can penetrate between the inorganic/passivation layer IOL and the protection/insulating layer ES, as well as between the inorganic/passivation layer IOL and the mask MSK, forming a tapered surface on the sidewall glass that overlaps in the thickness direction of the opening and the substrate.

As the etching process time increases, the tapered surface begins to form at the edge of the inorganic/passivation layer IOL exposed to the glass etching fluid GEF, and longer process times can result in a longer tapered surface. When the lower surface of the glass substrate 10 is exposed to the etching fluid GEF in the etching process, the thickness of a glass substrate 10 can be reduced, resulting in a longer tapered surface. The etching process can be stopped when the thickness of the glass substrate of the design value and the wedge shape of the cross section are reached.

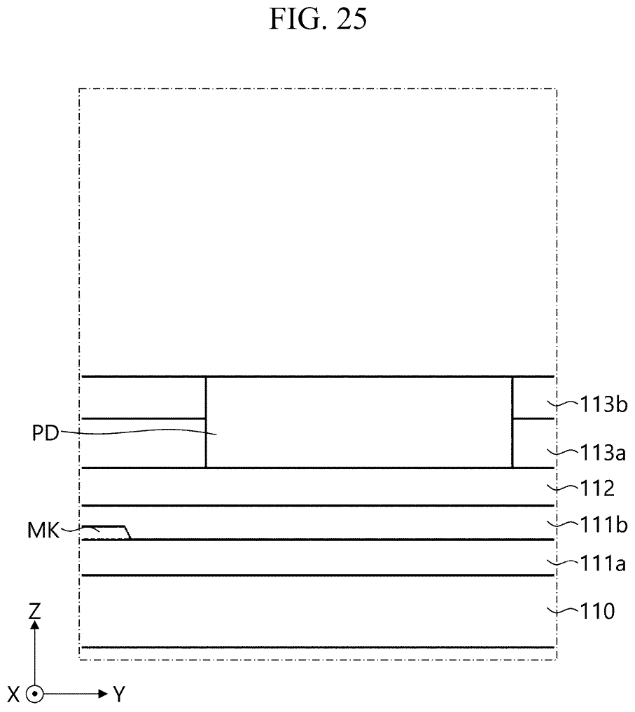

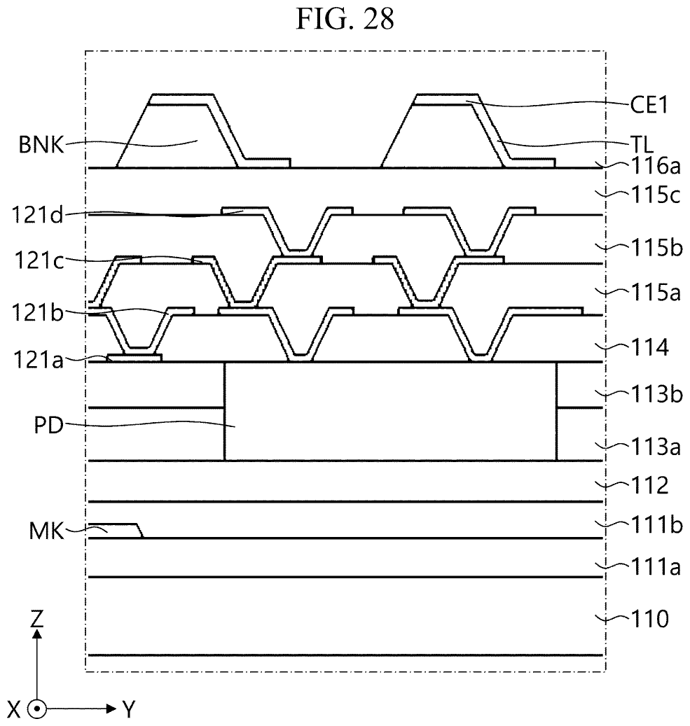

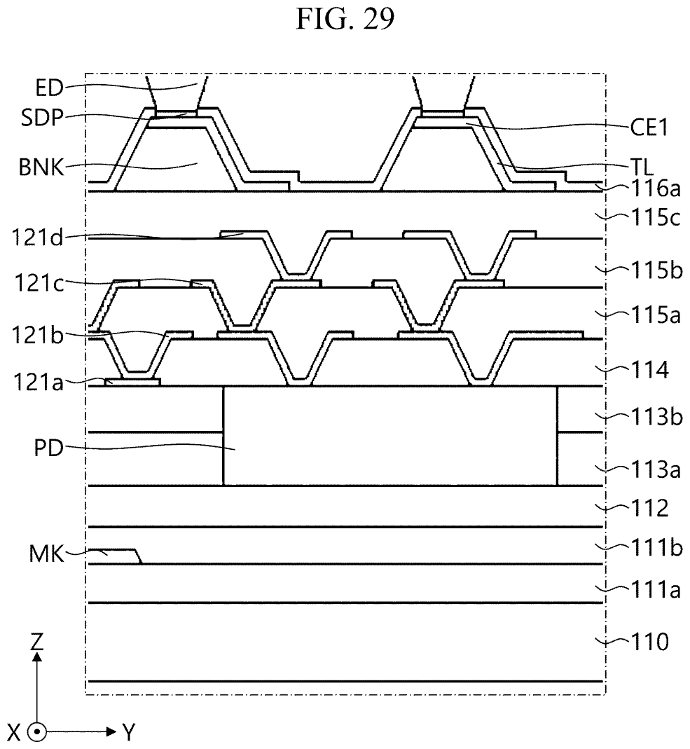

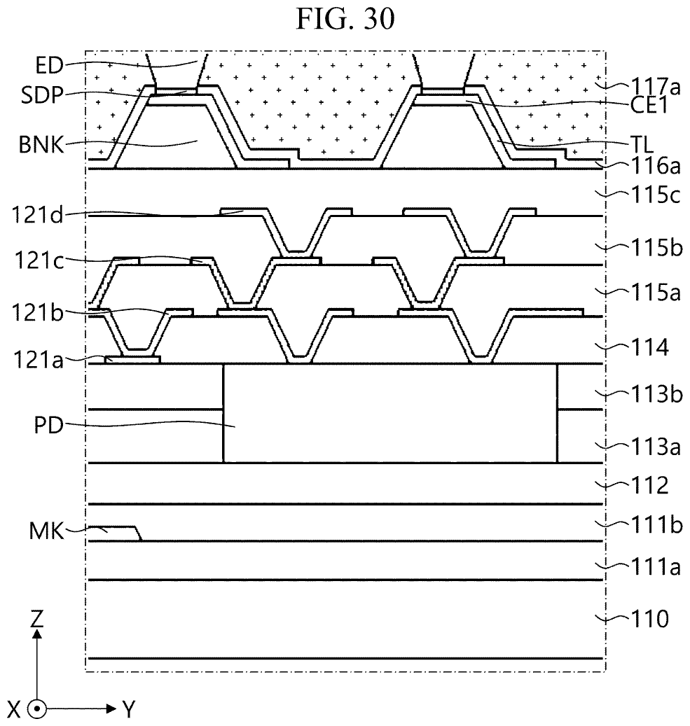

FIGS. 25 to 30 are diagrams illustrating the manufacturing process of the display device according to an embodiment of the present disclosure.

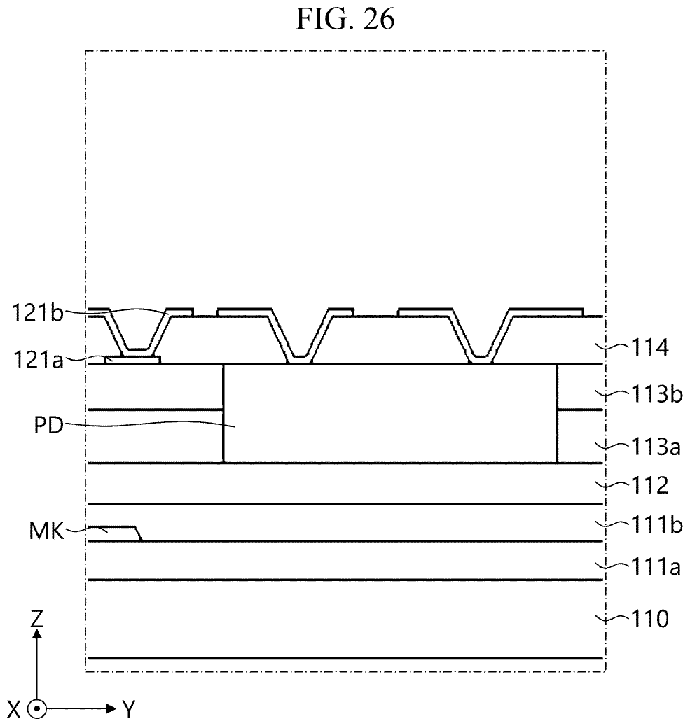

Referring to FIGS. 25 and 26, after the first-first connection wire 121a and the first-second connection wire 121b are formed, an electrical characteristic evaluation can be performed to confirm whether the pixel driving circuit PD and the first-second connection wire 121b are connected. Subsequent processes are carried out only for manufactured products that have passed the electrical characteristics evaluation. The electrical characteristic evaluation can be performed by connecting a probe card to test pads on the top of the display panel. Since the evaluation is conducted with the first-second connection wire 121b exposed, the exposure time to the process gas of the first-second connection wire can be prolonged due to the other connection wires 121a, 121c, and 121d. Therefore, compared to the other connection lines 121a, 121c, and 121d, the second metal layer of the first-second connection line 121b is relatively more likely to form reaction products with the gas and can have a relatively higher susceptibility to corrosion due to external moisture ingress.

When exposed to gas, the susceptibility to corrosion of the wire increases, leading to the problem that the lifespan of the display panel decreases as the amount of contact with the gas increases. Factors affecting the amount of contact with the gas can include, as described above, the thickness of the metal layer in contact with the gas for the same duration. Additionally, factors affecting the amount of contact with the gas can include the duration of exposure to the gas. As the exposure to the gas increases, the greater the effect of the gas exposure, which can shorten the lifespan of the display panel.

Therefore, the display panel according to an embodiment of the present disclosure preferentially dispose an inorganic layer on wires with prolonged exposure to the process gas during the manufacturing process, thereby extending the lifespan of the display panel and improving the operational reliability. As a result, the production energy of the display device can be reduced and its lifespan can be improved.

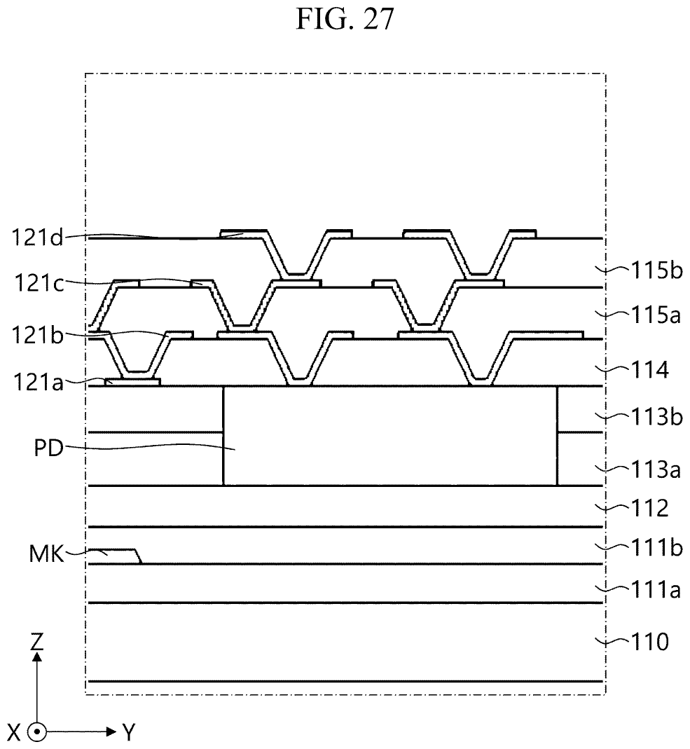

Referring to FIGS. 27 to 30, after the signal wire TL and light-emitting element ED are formed, the lighting evaluation can conducted. Subsequent processes are carried out only for manufactured products that have passed the lighting evaluation. As a subsequent process, the first optical layer 117a can be arranged. Since the evaluation is conducted with the signal wire TL exposed, the exposure time of the signal wire to the process gas can be prolonged due to the other connection wires 121a, 121c, and 121d. Therefore, compared to the other connection lines 121a, 121c, and 121d, the second metal layer of the signal line TL is relatively more likely to form reaction products with process gases and can have a relatively higher susceptibility to corrosion due to external moisture ingress.”

For substantially the same reasons as the first-second connection wire 121b described above, the display panel according to an embodiment of the present disclosure preferentially disposes a passivation layer or an inorganic layer on wires with prolonged exposure to the process gas during the manufacturing process, thereby extending the life of the display panel and improving operational reliability. As a result, the production energy of the display device can be reduced and its lifespan can be improved.

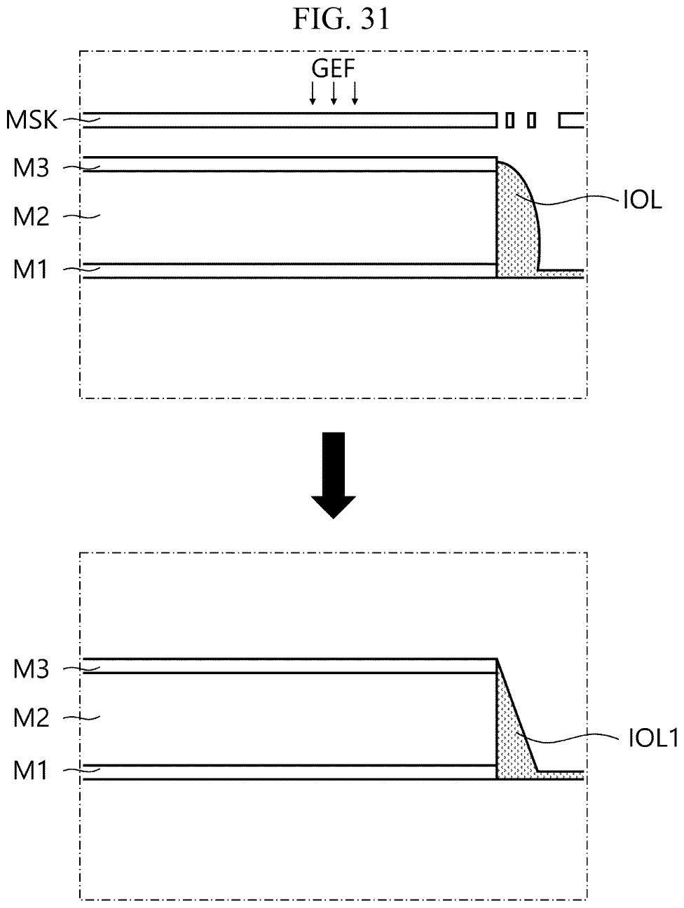

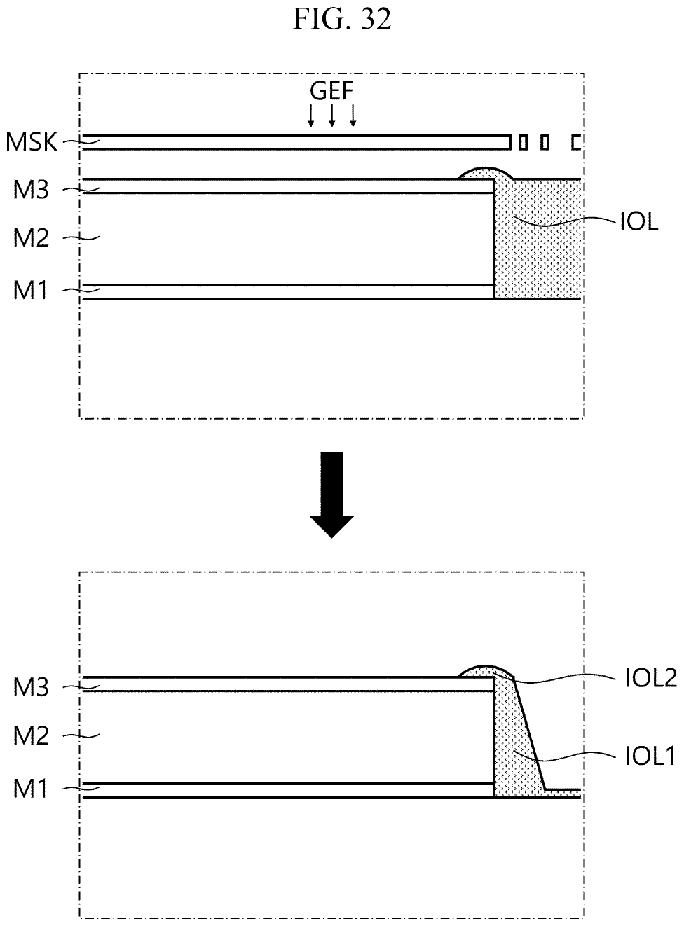

FIGS. 31 to 32 are diagrams illustrating the manufacturing process of the display device according to an embodiment of the present disclosure.

Referring to FIGS. 31 to 32, after forming the wire including the first metal layer M1, the second metal layer M2, and the third metal layer M3 is formed, a deposition process for an inorganic layer IOL can be performed. In a subsequent process, a mask MSK including a slit on its upper surface can be arranged. A plurality of slits can have different sizes depending on the shape of the etched surface. In a subsequent process, a strip process of spraying the etching fluid GEF and removing the residue can be performed. Depending on the implementation, an inorganic layer IOL1 covering the second metal layer and/or an inorganic layer IOL2 arranged on the third metal layer can be formed to adjust the border shape of the inorganic layer.

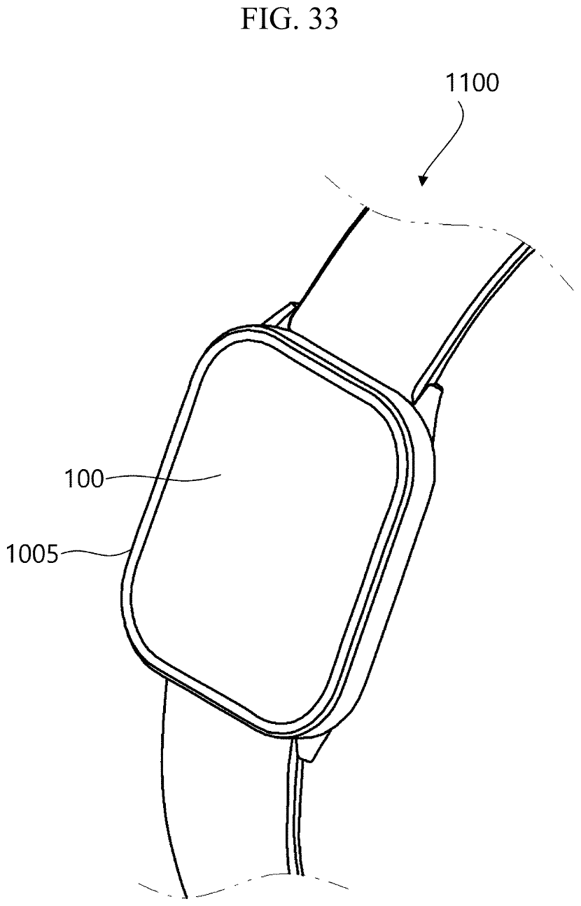

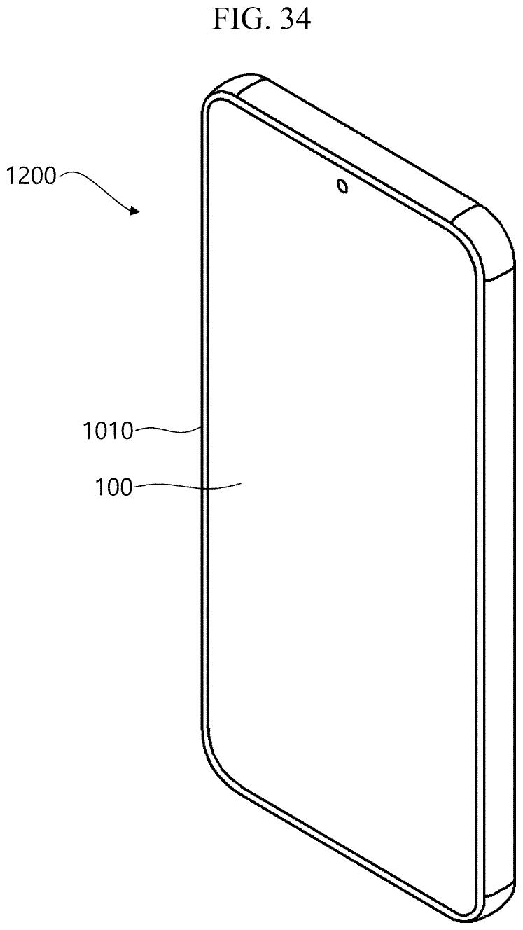

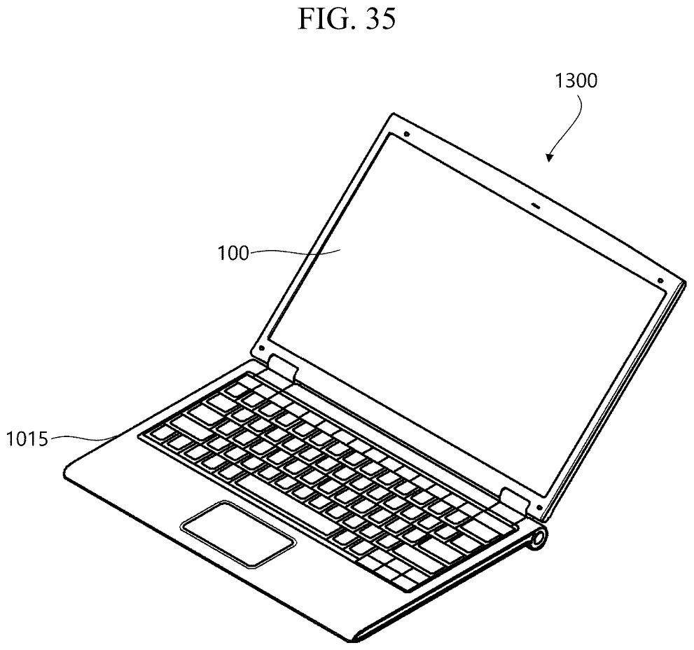

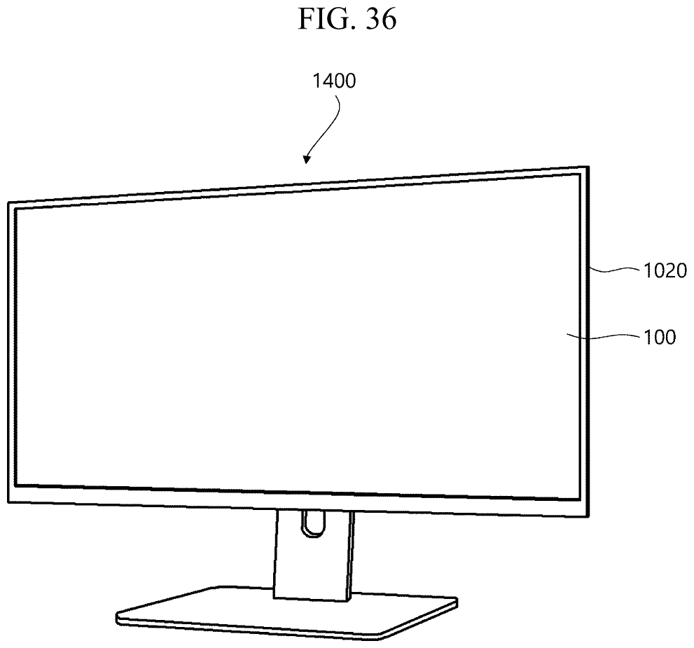

FIGS. 33 to 36 are diagrams illustrating an apparatus to which the display device according to embodiments of the present disclosure is applied.

Referring to FIGS. 33 to 36, the display device 1000 according to embodiments of the present disclosure can be included in a variety of devices or electronic devices. For example, referring to FIGS. 33 to 36, various electronic devices can include a wearable device 1100, a mobile device 1200, a laptop 1300, and a monitor or television (TV) 1400, but embodiments of the present disclosure are not limited thereto.

The wearable device 1100, the mobile device 1200, the laptop 1300, and the monitor or TV 1400 can include case parts 1005, 1010, 1015, and 1020, respectively, and can each include the display panel 100 and the display device 1000 according to the embodiments of the present disclosure described above.

For example, the display device according to the embodiment of the present disclosure can be applied to mobile devices, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, e-books, portable multimedia players (PMPs), personal digital assistants (PDAs), MP3 players, mobile medical devices, desktop personal computers (PCs) s, laptop PCs, netbook computers, workstations, navigation devices, vehicle display devices, theater display devices, televisions, wallpaper devices, signage devices, gaming devices, laptops, monitors, cameras, camcorders, household appliances, and the like.

The display device according to one or more embodiments of the present disclosure can be described as follows.

A display panel according to an embodiment of the present disclosure can include: a first-first connection wire, a first-second connection wire arranged on the first-first connection wire, a first inorganic layer arranged on the first-first connection wire, a first-third connection wire arranged on the first-second connection wire, a first-fourth connection wire arranged on the first-third connection wire, and a signal wire arranged on the first-fourth connection wire.

In the display panel according to the embodiment, the first-second connection wire can include: a first metal layer, a second metal layer arranged on the first metal layer, and a third metal layer arranged on the second metal layer.

In the display panel according to the embodiment, the first inorganic layer can include: a first-first inorganic layer covering an end of the second metal layer.

In the display panel according to the embodiment, the first inorganic layer can include: a first-second inorganic layer arranged on the third metal layer.

In the display panel according to the embodiment, the first metal layer and the third metal layer can be formed of the same material as each other.

The display panel according to an embodiment can further include: a first passivation layer arranged on the first-fourth connection wire.

In the display panel according to the embodiment, the signal wire can include: a first metal layer, a second metal layer arranged on the first metal layer, and a third metal layer arranged on the second metal layer.

In the display panel according to the embodiment, the first passivation layer can include: a second-first inorganic layer covering an end of the second metal layer and a second-second inorganic layer arranged on the third metal layer.

In the display panel according to the embodiment, the first-first inorganic layer and the second-first inorganic layer can have different thicknesses.

In the display panel according to the embodiment, each of the first-first connection wire, the first-third connection wire, and the first-fourth connection wire can include a first metal layer, a second metal layer arranged on the first metal layer, and a third metal layer arranged on the second metal layer.

The display panel according to the embodiment can further include: a third inorganic layer including a third-first inorganic layer covering an end of the second metallic layer of the first-first connection wire, a fourth inorganic layer including a fourth-first inorganic layer covering an end of the second metallic layer of the first-third connection wire, and a fifth inorganic layer including a fifth-first inorganic layer covering an end of the second metallic layer of the first-fourth connection wire.

The display panel according to the embodiment further include: a first electrode electrically connected to the signal wire and a light-emitting element electrically connected to the first electrode, wherein the light-emitting element can include: an anode electrode, a first semiconductor layer arranged on the anode electrode, an active layer arranged on the first semiconductor layer, a second semiconductor layer arranged on the active layer, and a cathode electrode arranged on the second semiconductor layer.

In the display panel according to the embodiment, the light-emitting element can have a vertical structure.

The display panel according to the embodiment can further include: a solder pattern arranged between the first electrode and the anode electrode, wherein the first electrode and the anode electrode can be electrically connected by an eutectic bonding via the solder pattern.

A display panel according to an embodiment of the present disclosure can include: a first-first connection wire, a first-second connection wire arranged on the first-first connection wire, a first-third connection wire arranged on the first-second connection wire, a first-fourth connection wire arranged on the first-third connection wire, and a first passivation layer arranged on the first-fourth connection wire.

In the display panel according to the embodiment, the signal wire can include: a first metal layer, a second metal layer arranged on the first metal layer, and a third metal layer arranged on the second metal layer.

In the display panel according to the embodiment, the first passivation layer can include: a second-first inorganic layer covering an end of the second metal layer.

In the display panel according to the embodiment, the first passivation layer can include: a second-second inorganic layer arranged on the third metal layer.

The display panel according to an embodiment can further include: a first inorganic layer arranged on the first-first connection wire.

In the display panel according to the embodiment, the first-second connection wire can include: a first metal layer, a second metal layer arranged on the first metal layer, and a third metal layer arranged on the second metal layer.

In the display panel according to the embodiment, the first inorganic layer can include: a first-first inorganic layer covering an end of the second metal layer and a first-second inorganic layer arranged on the third metal layer.

In the display panel according to the embodiment, each of the first-first connection wire, the first-third connection wire, and the first-fourth connection wire can include a first metal layer, a second metal layer arranged on the first metal layer, and a third metal layer arranged on the second metal layer.

The display panel according to the embodiment can further include: a third inorganic layer including a third-first inorganic layer covering an end of the second metallic layer of the first-first connection wire, a fourth inorganic layer including a fourth-first inorganic layer covering an end of the second metallic layer of the first-third connection wire, and a fifth inorganic layer including a fifth-first inorganic layer covering an end of the second metallic layer of the first-fourth connection wire.

The display panel according to the embodiment further include: a first electrode electrically connected to the signal wire and a light-emitting element electrically connected to the first electrode, wherein the light-emitting element can include: an anode electrode, a first semiconductor layer arranged on the anode electrode, an active layer arranged on the first semiconductor layer, a second semiconductor layer arranged on the active layer, and a cathode electrode arranged on the second semiconductor layer.

In the display panel according to the embodiment, the light-emitting element can have a vertical structure.

The display panel according to the embodiment can further include: a solder pattern arranged between the first electrode and the anode electrode, wherein the first electrode and the anode electrode can be electrically connected by an eutectic bonding via the solder pattern.

Accordingly, the embodiments disclosed herein are to be considered descriptive and not restrictive of the technical spirit of the present invention, and the scope of the technical spirit of the present invention is not limited by these embodiments.

Accordingly, the above-described embodiments should be understood to be as examples and not limiting in any aspect.

The scope of the present invention should be construed by the appended claims, and all technical ideas within the scope of their equivalents should be construed as being included in the scope of the present invention.

What is claimed is:

1. A display panel comprising:
a substrate having a display area and a non-display area,
wherein the display area includes:
a first-first connection wire;
a first-second connection wire arranged on the first-first connection wire;
a first-third connection wire arranged on the first-second connection wire;
a first-fourth connection wire arranged on the first-third connection wire; and
a signal wire arranged on the first-fourth connection wire, and
wherein at least one protective layer is arranged on the first-first connection wire or the first-fourth connection wire.

2. The display panel of claim 1, wherein the at least one protective layer includes a first inorganic layer arranged on the first-first connection wire.

3. The display panel of claim 2, wherein the first-second connection wire includes:
a first metal layer;
a second metal layer arranged on the first metal layer; and
a third metal layer arranged on the second metal layer.

4. The display panel of claim 3, wherein the first inorganic layer include a first-first inorganic layer covering an end of the second metal layer.

5. The display panel of claim 4, wherein the first inorganic layer includes a first-second inorganic layer arranged on the third metal layer.

6. The display panel of claim 3, wherein the first metal layer and the third metal layer are formed of the same material.

7. The display panel of claim 4, wherein the at least one protective layer further includes a first passivation layer arranged on the first-fourth connection wire.

8. The display panel of claim 7, wherein the signal wire includes:
a first metal layer;
a second metal layer arranged on the first metal layer; and
a third metal layer arranged on the second metal layer.

9. The display panel of claim 8, wherein the first passivation layer includes:
a second-first inorganic layer covering an end of the second metal layer; and
a second-second inorganic layer arranged on the third metal layer.

10. The display panel of claim 9, wherein the first-first inorganic layer and the second-first inorganic layer have different thicknesses.

11. The display panel of claim 1, wherein each of the first-first connection wire, the first-third connection wire, and the first-fourth connection wire includes:
a first metal layer;
a second metal layer arranged on the first metal layer; and
a third metal layer arranged on the second metal layer.

12. The display panel of claim 11, further comprising:
a third inorganic layer including a third-first inorganic layer covering an end of the second metallic layer of the first-first connection wire;
a fourth inorganic layer including a fourth-first inorganic layer covering an end of the second metal layer of the first-third connection wire; and
a fifth inorganic layer including a fifth-first inorganic layer covering an end of the second metal layer of the first-fourth connection wire.

13. The display panel of claim 1, further comprising:
a first electrode electrically connected to the signal wire; and
a light-emitting element electrically connected to the first electrode,
wherein the light-emitting element includes:
an anode electrode;
a first semiconductor layer arranged on the anode electrode;
an active layer arranged on the first semiconductor layer;
a second semiconductor layer arranged on the active layer; and
a cathode electrode arranged on the second semiconductor layer.

14. The display panel of claim 13 wherein the light-emitting element has a vertical structure.

15. The display panel of claim 13, further comprising:
a pattern layer arranged between the first electrode and the anode electrode,
wherein the first electrode and the anode electrode are electrically connected by an eutectic junction via the solder pattern.

16. The display panel of claim 1, wherein the at least one protective layer is a first passivation layer arranged on the first-fourth connection wire.

17. The display panel of claim 1, wherein the non-display area includes:
a second-first connection wire;
a second-second connection wire arranged on the second-first connection wire;
a second-third connection wire arranged on the second-second connection wire; and
a second-fourth connection wire arranged on the second-third connection wire.

18. The display panel of claim 15, wherein the first passivation layer is a single layer or multiple layers of silicon oxide (SiOx) or silicon nitride (SiNx).

19. The display panel of claim 13, further comprising:
a first optical layer arranged to surround the light emitting element;
a second optical layer arranged on the first optical layer; and
a third optical layer arranged to abut the first optical layer.

20. A display panel comprising:
a substrate having a display area and a non-display area,
wherein the display area includes:
a first-first connection wire;
a first-second connection wire arranged on the first-first connection wire;
a first-third connection wire arranged on the first-second connection wire;
a first-fourth connection wire arranged on the first-third connection wire; and
a signal wire arranged on the first-fourth connection wire, and
wherein at least one protective layer has:
a first portion arranged to cover an end of the first-first connection wire or an end of the first-fourth connection wire, and
a second portion that extends from the first portion and is planar on an underlaying layer.
